(19) United States
(12) Patent Application Publication
(10) Pub. No.: US 2026/0114022 A1
(43) Pub. Date: Apr. 23, 2026

(54) SEMICONDUCTOR DEVICE AND MANUFACTURING METHODS OF THE SAME

(71) Applicant: Samsung Electronics Co., Ltd., Suwon-si (KR)

(72) Inventors: Byung Ho MOON, Suwon-si (KR); Min Woo KIM, Suwon-si (KR); Dong Hoon HWANG, Suwon-si (KR); Jae Ho JEON, Suwon-si (KR); Seong Kwang KIM, Suwon-si (KR); Hyun Soo KIM, Suwon-si (KR); Won Chang LEE, Suwon-si (KR)

(73) Assignee: Samsung Electronics Co., Ltd., Suwon-si (KR)

(21) Appl. No.: 19/338,626

(22) Filed: Sep. 24, 2025

(30) Foreign Application Priority Data
Oct. 23, 2024 (KR) 10-2024-0145470

(51) Int. Cl. H10D 84/01; H10D 84/85

(52) U.S. Cl. CPC H10D 84/0188; H10D 84/851; H10D 84/856

(57) ABSTRACT

A semiconductor device including first and second active patterns extending in a first horizontal direction on a substrate, the first and second active patterns spaced apart in a second horizontal direction; a field insulating layer on the substrate and surrounding sidewalls of the first and second active patterns; first and second gate electrodes respectively extending in the second horizontal direction on the first and second active patterns, the first and second gate electrodes spaced apart in the second horizontal direction; and a gate cut separating the first and second gate electrodes in the second horizontal direction. The gate cut including a first portion partially inside the field insulating layer, and a second portion vertically extending on the first portion. Sidewalls of the second portion have continuous sloped profile. A width of a bottom of the second portion is greater than a width of a top of the second portion.

### CROSS-REFERENCE TO RELATED APPLICATION

This application claims priority from Korean Patent Application No. 10-2024-0145470 filed on Oct. 23, 2024 in the Korean Intellectual Property Office, and all the benefits accruing therefrom under 35 U.S.C. 119, the contents of which in its entirety are herein incorporated by reference.

### BACKGROUND

The present disclosure relates to semiconductor devices. More particularly, the present disclosure relates to semiconductor devices including a MBCFET™ (Multi-Bridge Channel Field Effect Transistor) and manufacturing methods of the same.

As one of the scaling techniques to increase the density of integrated circuit devices, multi-gate transistors have been proposed, in which a fin-shaped or nanowire-shaped silicon body is formed on a substrate, and gates are formed on the surface of the silicon body.

Since these multi-gate transistors utilize a three-dimensional channel, they are easy to scale. For example, the current control capability may be improved without increasing the gate length of the multi-gate transistor. Furthermore, the SCE (short channel effect), in which the potential of the channel region is influenced by the drain voltage, may be effectively suppressed.

### SUMMARY

The present disclosure provides a semiconductor device that improves the reliability of a gate cut and reduces the process difficulty of manufacturing the gate cut.

The aspects of the present disclosure are not limited to those mentioned above and other aspects which are not mentioned may be clearly understood by those skilled in the art from the description below.

Some example embodiments of the present disclosure provide a semiconductor device including a substrate; a first active pattern on an upper surface of the substrate, the first active pattern extending in a first horizontal direction; a second active pattern on the upper surface of the substrate, the second active pattern extending in the first horizontal direction, and the second active pattern being spaced apart from the first active pattern in a second horizontal direction different from the first horizontal direction; a field insulating layer on the upper surface of the substrate, the field insulating layer surrounding sidewalls of the first active pattern and the second active pattern; a first gate electrode on the first active pattern, the first gate electrode extending in the second horizontal direction; a second gate electrode on the second active pattern, the second gate electrode extending in the second horizontal direction, and the second gate electrode being spaced apart from the first gate electrode in the second horizontal direction; and a gate cut separating the first gate electrode and the second gate electrode in the second horizontal direction, the gate cut including a first portion at least partially inside the field insulating layer and a second portion on an upper surface of the first portion, the second portion extending in a vertical direction. Sidewalls of the second portion of the gate cut that are opposite each other in the second horizontal direction have continuous sloped profile. A width along the second horizontal direction of a bottom surface of the second portion of the gate cut is greater than a width along the second horizontal direction of an upper surface of the second portion of the gate cut.

Some example embodiments of the present disclosure further provide a semiconductor device including a substrate; a first active pattern on an upper surface of the substrate, the first active pattern extending in a first horizontal direction; a second active pattern on the upper surface of the substrate, the second active pattern extending in the first horizontal direction, the second active pattern being spaced apart from the first active pattern in a second horizontal direction different from the first horizontal direction; a first plurality of bottom nanosheets stacked on the first active pattern, the first plurality of bottom nanosheets being spaced apart from each other in a vertical direction; a second plurality of bottom nanosheets stacked on the second active pattern, the second plurality of bottom nanosheets being spaced apart from each other in the vertical direction, and the second plurality of bottom nanosheets being spaced apart from the first plurality of bottom nanosheets in the second horizontal direction; a first gate electrode on the first active pattern, the first gate electrode extending in the second horizontal direction, and the first gate electrode surrounding the first plurality of bottom nanosheets; a second gate electrode on the second active pattern, the second gate electrode extending in the second horizontal direction, the second gate electrode being spaced apart from the first gate electrode in the second horizontal direction, and the second gate electrode surrounding the second plurality of bottom nanosheets; and a gate cut between the first plurality of bottom nanosheets and the second plurality of bottom nanosheets, the gate cut separating the first gate electrode and the second gate electrode in the second horizontal direction, and the gate cut contacting the first gate electrode and the second gate electrode, the gate cut including a first portion, and a second portion on an upper surface of the first portion, the first portion and the second portion extending in the vertical direction. Sidewalls of the second portion of the gate cut that are opposite each other in the second horizontal direction have continuous sloped profile. A width along the second horizontal direction of a bottom surface of the second portion of the gate cut is greater than a width along the second horizontal direction of an upper surface of the second portion of the gate cut.

Some example embodiments of the present disclosure still further provide a semiconductor device including a substrate; a first active pattern on an upper surface of the substrate, the first active pattern extending in a first horizontal direction; a second active pattern on the upper surface of the substrate, the second active pattern extending in the first horizontal direction, and the second active pattern being spaced apart from the first active pattern in a second horizontal direction different from the first horizontal direction; a field insulating layer on the upper surface of the substrate, the field insulating layer surrounding sidewalls of the first active pattern and the second active pattern; a first plurality of bottom nanosheets stacked on the first active pattern, the first plurality of bottom nanosheets being spaced apart from each other in a vertical direction; a second plurality of bottom nanosheets stacked on the second active pattern, the second plurality of bottom nanosheets being spaced apart from each other in the vertical direction, and the second plurality of bottom nanosheets being spaced apart from the first plurality of bottom nanosheets in the second horizontal direction; a first nanosheet isolation layer on an upper surface of an uppermost nanosheet of the first plurality of bottom nanosheets, the first nanosheet isolation layer including a first insulating material; a second nanosheet isolation layer on an upper surface of an uppermost nanosheet of the second plurality of bottom nanosheets, the second nanosheet isolation layer including a second insulating material; a first plurality of upper nanosheets stacked on an upper surface of the first nanosheet isolation layer, the first plurality of upper nanosheets being spaced apart from each other in the vertical direction; a second plurality of upper nanosheets stacked on an upper surface of the second nanosheet isolation layer, the second plurality of upper nanosheets being spaced apart from each other in the vertical direction; a first gate electrode on the first active pattern, the first gate electrode extending in the second horizontal direction, and the first gate electrode surrounding each of the first plurality of bottom nanosheets, the first nanosheet isolation layer, and the first plurality of upper nanosheets; a second gate electrode on the second active pattern, the second gate electrode extending in the second horizontal direction, the second gate electrode being spaced apart from the first gate electrode in the second horizontal direction, and the second gate electrode surrounding each of the second plurality of bottom nanosheets, the second nanosheet isolation layer, and the second plurality of upper nanosheets; a first gate spacer on sidewalls of the first gate electrode that are opposite each other in the first horizontal direction; a second gate spacer on sidewalls of the second gate electrode that are opposite each other in the first horizontal direction, the second gate spacer being spaced apart from the first gate spacer in the second horizontal direction; and a gate cut between the first plurality of bottom nanosheets and the second plurality of bottom nanosheets, the gate cut separating the first gate electrode and the second gate electrode from each other in the second horizontal direction, the gate cut separating the first gate spacer and the second gate spacer from each other in the second horizontal direction, and the gate cut being in contact with the first gate electrode and the second gate electrode. The gate cut including a first portion at least partially inside of the field insulating layer, and a second portion on an upper surface of the first portion, the second portion extending in the vertical direction. A sidewall of the second portion of the gate cut along the second horizontal direction has a continuous sloped profile. A width along the second horizontal direction of a bottom surface of the second portion of the gate cut is greater than a width along the second horizontal direction of an upper surface of the second portion of the gate cut. A width along the second horizontal direction of the gate cut between the first gate spacer and the second gate spacer is greater than a width along the second horizontal direction of the gate cut between the first gate electrode and the second gate electrode.

Some example embodiments of the present disclosure further provide a manufacturing method for a semiconductor device including forming first and second active patterns on an upper surface of a substrate, the first and second active patterns extending in a first horizontal direction, and the first and second active patterns being spaced apart from each other in a second horizontal direction different from the first horizontal direction; forming a field insulation layer on the upper surface of the substrate, the field insulation layer surrounding the first and second active patterns; forming a first plurality of bottom nanosheets stacked on the first active pattern in a vertical direction; forming a second plurality of bottom nanosheets stacked on the second active pattern in the vertical direction; forming a conductive layer on the first active pattern and the second active pattern, the conductive layer extending in the second horizontal direction, and the conductive layer surrounding the first plurality of bottom nanosheets an the second plurality of bottom nanosheets; forming a gate cut on the field insulation layer between the first and second plurality of bottom nanosheets along the second horizontal direction, the gate cut extending through the conductive layer, and the gate cut separating the conductive layer along the second horizontal direction; and after the forming of the gate cut, forming a filling conductive layer on the conductive layer, the filling conductive layer contacting the gate cut, and the gate cut separating the filling conductive layer in the second horizontal direction.

In some example embodiments of the manufacturing method for a semiconductor device, the forming of the gate cut includes forming a first portion of the gate cut at least partially inside the field insulating layer, and forming a second portion of the gate cut on an upper surface of the first portion, the second portion extending in a vertical direction on the second portion.

In some example embodiments of the manufacturing method for a semiconductor device, the manufacturing method further includes forming a first nanosheet isolation layer on an upper surface of an uppermost nanosheet of the first plurality of bottom nanosheets; forming a second nanosheet isolation layer on an upper surface of an uppermost nanosheet of the second plurality of bottom nanosheets; forming a first plurality of upper nanosheets stacked on an upper surface of the first nanosheet isolating layer; and forming a second plurality of upper nanosheets stacked on an upper surface of the second nanosheet isolating layer. The second portion of the gate cut is between the first and second plurality of bottom nanosheets along the second horizontal direction, and between the first and second plurality of upper nanosheets along the second horizontal direction.

In some example embodiments of the manufacturing method for a semiconductor device, the conductive layer surrounds a portion of the first nanosheet isolation layer, and surrounds a portion of the second nanosheet isolation layer.

In some example embodiments of the manufacturing method for a semiconductor device, the filling conductive layer surrounds another portion of the first nanosheet isolation layer, the first plurality of upper nanosheets, another portion of the second nanosheet isolation layer and the second plurality of upper nanosheets.

In some example embodiments of the manufacturing method for a semiconductor device, the forming of the gate cut includes forming sidewalls of the second portion that are opposite to each other in the second horizontal direction as having continuous sloped profile.

In some example embodiments of the manufacturing method for a semiconductor device, the forming of the gate cut includes forming a bottom surface of the second portion as having a width along the second horizontal direction that is greater than a width along the second horizontal direction of an upper surface of the second portion.

In some example embodiments of the manufacturing method for a semiconductor device, the forming of the gate cut further includes forming the upper surface of the first portion as having a width along the horizontal direction that is greater than the width along the horizontal direction of the bottom surface of the second portion.

In some example embodiments of the manufacturing method for a semiconductor device, the manufacturing method includes forming a capping pattern on upper surfaces of the filling conductive layer, the capping pattern extending in the second horizontal direction.

In some example embodiments of the manufacturing method for a semiconductor device, sidewalls of the second portion of the gate cut that are opposite to each other in the second horizontal direction contact the capping pattern.

In some example embodiments of the manufacturing method for a semiconductor device, the upper surface of the second portion of the gate cut contacts a bottom surface of the capping pattern.

In some example embodiments of the manufacturing method for a semiconductor device, the manufacturing method further includes forming a first gate spacer on sidewalls of the filling conductive layer over the first plurality of upper nanosheets; and forming a second gate spacer on sidewalls of the filling conductive layer over the second plurality of upper nanosheets. The gate cut separates the first gate spacer from the second gate spacer along the second horizontal direction.

In some example embodiments of the manufacturing method for a semiconductor device, sidewalls of the second portion of the gate cut that are opposite each other along the second horizontal direction contact the first and second gate spacers.

In some example embodiments of the manufacturing method for a semiconductor device, a width of the gate cut that separates the first gate spacer from the second gate spacer along the second horizontal direction is greater than a width of the gate cut that separates the filling conductive layer along the second horizontal direction.

In some example embodiments of the manufacturing method for a semiconductor device, the forming of the gate cut includes forming the second portion so that a distance along the second horizontal direction between the first plurality of bottom nanosheets and the second portion of the gate cut is greater than a distance along the second horizontal direction between the first active pattern and the first portion of the gate cut.

### BRIEF DESCRIPTION OF THE DRAWINGS

The above and other aspects and features of the present disclosure will become more apparent in view of the following detailed description of some example embodiments thereof with reference to the attached drawings, in which:

FIG. 1 is a layout diagram for explaining a semiconductor device according to some example embodiments of the present disclosure;

FIG. 2 is a cross-sectional view taken along line A-A′ of FIG. 1;

FIG. 3 is a cross-sectional view taken along line B-B′ of FIG. 1;

FIG. 4 is a cross-sectional view taken along line C-C′ of FIG. 1;

FIGS. 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45 and 46 are intermediate stage diagrams for explaining a fabrication method of a semiconductor device according to some example embodiments of the present disclosure;

FIG. 47 is a cross-sectional view for explaining a semiconductor device according to some example embodiments of the present disclosure;

FIG. 48 is a cross-sectional view for explaining a semiconductor device according to some example embodiments of the present disclosure;

FIG. 49 is a layout view for explaining a semiconductor device according to some example embodiments of the present disclosure;

FIG. 50 is a cross-sectional view taken along line A-A′ of FIG. 49;

FIG. 51 is a cross-sectional view taken along line B-B′ of FIG. 49;

FIG. 52 is a cross-sectional view taken along line C-C′ of FIG. 49; and

FIGS. 53, 54, 55, 56, 57, 58, 59, 60 and 61 are intermediate stage diagrams for explaining a fabrication method of a semiconductor device according to some example embodiments of the present disclosure.

### DETAILED DESCRIPTION

In the following diagrams of a semiconductor device according to some example embodiments, the semiconductor device is described as including, by way of example, a transistor MBCFET™ (Multi-Bridge Channel Field Effect Transistor) that includes nanosheets, but the present disclosure is not limited thereto. In some example embodiments, the semiconductor device may include a fin-shaped transistor (FinFET) having a fin-shaped patterned channel region, a tunneling transistor (tunneling FET), or a three-dimensional (3D) transistor. For example, the semiconductor device according to some example embodiments may include bipolar junction transistors or laterally-diffused metal-oxide semiconductor (LDMOS) transistors, among others.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

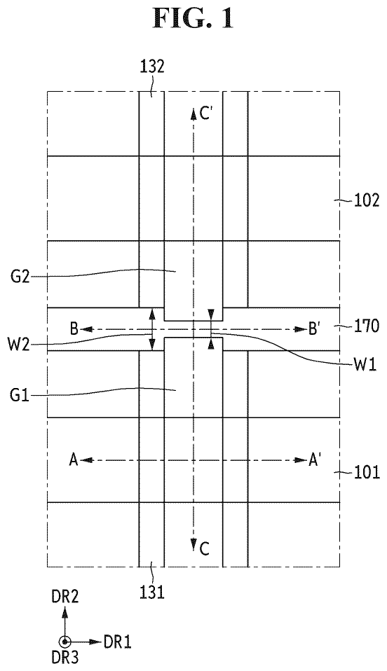

Hereinafter, a semiconductor device according to some example embodiments of the present disclosure will be described with reference to FIGS. 1 to 4.

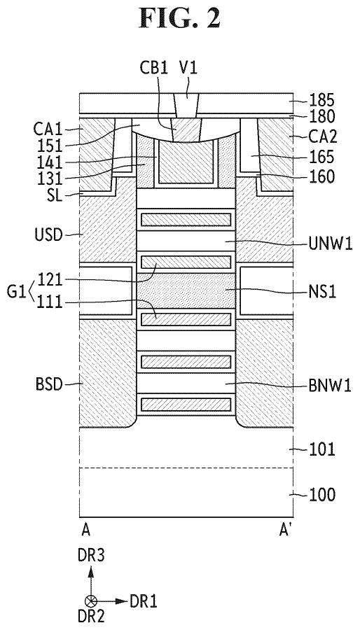

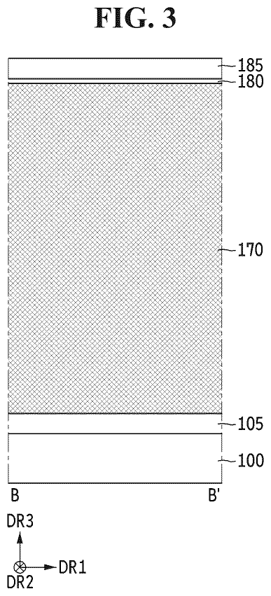

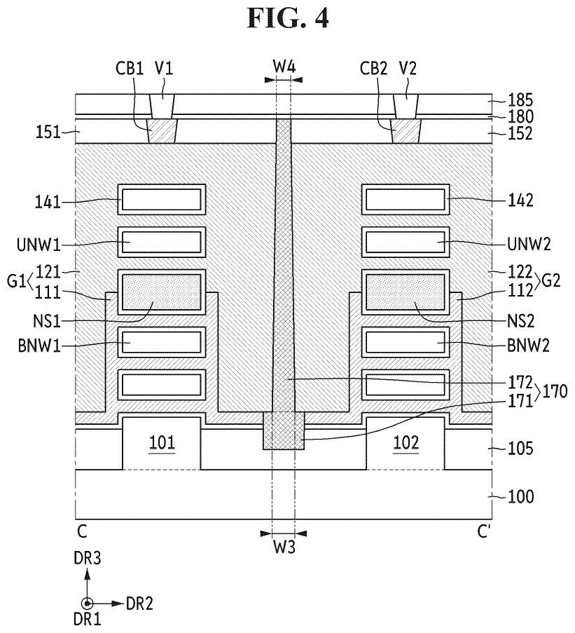

FIG. 1 is a layout diagram for explaining a semiconductor device according to some example embodiments of the present disclosure. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1.

Referring now to FIGS. 1 to 4, a semiconductor device according to some example embodiments of the present disclosure includes a substrate 100, first and second active patterns 101, 102, a field insulating layer 105, first and second plurality of bottom nanosheets BNW1, BNW2, first and second nanosheet isolation layers NS1, NS2, first and second plurality of upper nanosheets UNW1, UNW2, first and second gate electrodes G1, G2, first and second gate spacers 131, 132, first and second gate insulating layers 141, 142, first and second capping patterns 151, 152, a bottom source/drain region BSD, an upper source/drain region USD, a first etching stop layer 160, and a first interlayer insulating layer 165, a gate cut 170, first and second source/drain contacts CA1, CA2, a silicide layer SL, first and second gate contacts CB1, CB2, a second etching stop layer 180, a second interlayer insulating layer 185, and first and second vias V1, V2.

The substrate 100 may be a silicon substrate or an SOI (silicon-on-insulator) substrate. Alternatively, the substrate 100 may include silicon germanium, SGOI (silicon germanium on insulator), indium antimonide, lead tellurium compounds, indium arsenide, indium phosphide, gallium arsenide, or gallium antimonide, but the present disclosure is not limited thereto.

Hereinafter, each of the first horizontal direction DR1 and the second horizontal direction DR2 may be defined as a direction parallel to the upper surface of the substrate 100. The second horizontal direction DR2 may be defined as a different direction from the first horizontal direction DR1. The vertical direction DR3 may be defined as a direction perpendicular to each of the first horizontal direction DR1 and the second horizontal direction DR2. For example, the vertical direction DR3 may be defined as a direction perpendicular to the upper surface of the substrate 100.

The first active pattern 101 may extend in the first horizontal direction DR1 on an upper surface of the substrate 100. The second active pattern 102 may extend in the first horizontal direction DR1 on the upper surface of the substrate 100. The second active pattern 102 may be spaced apart from the first active pattern 101 in the second horizontal direction DR2. Each of the first and second active patterns 101, 102 may protrude in the vertical direction DR3 from the upper surface of the substrate 100. For example, each of the first and second active patterns 101, 102 may be part of the substrate 100, or may include an epitaxial layer grown from the substrate 100.

The field insulating layer 105 may be disposed on the upper surface of the substrate 100. The field insulating layer 105 may surround the sidewalls of each of the first and second active patterns 101, 102. For example, the upper surface of each of the first and second active patterns 101, 102 may protrude in the vertical direction DR3 more than (e.g., above) the upper surface of the field insulating layer 105. However, the present disclosure is not limited thereto. In some example embodiments, the upper surface of each of the first and second active patterns 101, 102 may be formed on the same plane as the upper surface of the field insulating layer 105. The field insulating layer 105 may include, for example, an oxide layer, a nitride layer, an oxynitride layer, or a combination thereof.

The first plurality of bottom nanosheets BNW1 may be disposed on the first active pattern 101. The first plurality of bottom nanosheets BNW1 may be spaced apart from the upper surface of the first active pattern 101 in the vertical direction DR3. The first plurality of bottom nanosheets BNW1 may include a plurality of nanosheets stacked and spaced apart from each other in the vertical direction DR3 on the first active pattern 101. The second plurality of bottom nanosheets BNW2 may be disposed on the second active pattern 102. The second plurality of bottom nanosheets BNW2 may be spaced apart from the upper surface of the second active pattern 102 in the vertical direction DR3. The second plurality of bottom nanosheets BNW2 may be spaced apart from the first plurality of bottom nanosheets BNW1 in the second horizontal direction DR2. The second plurality of bottom nanosheets BNW2 may include a plurality of nanosheets stacked and spaced apart from each other in the vertical direction DR3 on the second active pattern 102.

In FIGS. 2 and 4, each of the first and second plurality of bottom nanosheets BNW1, BNW2 is shown as including two nanosheets stacked and spaced apart from each other in the vertical direction DR3, but the present disclosure is not limited thereto. In some example embodiments, each of the first and second plurality of bottom nanosheets BNW1, BNW2 may include three or more nanosheets stacked and spaced apart from each other in the vertical direction DR3. For example, each of the first and second plurality of bottom nanosheets BNW1, BNW2 may contain silicon (Si).

The first nanosheet isolation layer NS1 may be disposed on the upper surface of the uppermost nanosheet of the first plurality of bottom nanosheets BNW1. For example, the first nanosheet isolation layer NS1 may be spaced apart from the upper surface of the uppermost nanosheet of the first plurality of bottom nanosheets BNW1 in the vertical direction DR3. The second nanosheet isolation layer NS2 may be disposed on the upper surface of the uppermost nanosheet of the second plurality of bottom nanosheets BNW2. For example, the second nanosheet isolation layer NS2 may be spaced apart from the upper surface of the uppermost nanosheet of the second plurality of bottom nanosheets BNW2 in the vertical direction DR3. The second nanosheet isolation layer NS2 may be spaced apart from the first nanosheet isolation layer NS1 in the second horizontal direction DR2. Each of the first and second nanosheet isolation layers NS1, NS2 may include an insulating material. For example, each of the first and second nanosheet isolation layers NS1, NS2 may include at least one of silicon nitride (SiN), silicon oxycarbonitride (SiOCN), silicon boron carbonitride (SiBCN), silicon carbonitride (SiCN), silicon oxynitride (SiON), and combinations thereof. However, the present disclosure is not limited thereto.

The first plurality of upper nanosheets UNW1 may be disposed on the upper surface of the first nanosheet isolation layer NS1. For example, the lowermost nanosheet of the first plurality of upper nanosheets UNW1 may be spaced apart from the upper surface of the first nanosheet isolation layer NS1 in the vertical direction DR3. The first plurality of upper nanosheets UNW1 may include a plurality of nanosheets stacked and spaced apart from each other in the vertical direction DR3 on the first nanosheet isolation layer NS1. The second plurality of upper nanosheets UNW2 may be disposed on the upper surface of the second nanosheet isolation layer NS2. For example, the lowermost nanosheet of the second plurality of upper nanosheets UNW2 may be spaced apart from the upper surface of the second nanosheet isolation layer NS2 in the vertical direction DR3. The second plurality of upper nanosheets UNW2 may be spaced apart from the first plurality of upper nanosheets UNW1 in the second horizontal direction DR2. The second plurality of upper nanosheets UNW2 may include a plurality of nanosheets stacked and spaced apart from each other in the vertical direction DR3 on the second nanosheet isolation layer NS2.

In FIGS. 2 and 4, each of the first and second plurality of upper nanosheets UNW1, UNW2 is shown as including two nanosheets stacked and spaced apart from each other in the vertical direction DR3, but the present disclosure is not limited thereto. In some example embodiments, each of the first and second plurality of upper nanosheets UNW1, UNW2 may include three or more nanosheets stacked and spaced apart from each other in the vertical direction DR3. For example, each of the first and second plurality of upper nanosheets UNW1, UNW2 may contain silicon (Si).

The first gate electrode G1 may extend in the second horizontal direction DR2 on the first active pattern 101. The first gate electrode G1 may surround each of the first plurality of bottom nanosheets BNW1, the first nanosheet isolation layer NS1, and the first plurality of upper nanosheets UNW1. The second gate electrode G2 may extend in the second horizontal direction DR2 on the second active pattern 102. The second gate electrode G2 may surround each of the second plurality of bottom nanosheets BNW2, the second nanosheet isolation layer NS2, and the second plurality of upper nanosheets UNW2. The second gate electrode G2 may be spaced apart from the first gate electrode G1 in the second horizontal direction DR2.

For example, the first gate electrode G1 may include a first conductive layer 111 and a first filling conductive layer 121. The first conductive layer 111 may be disposed on the upper surface of the field insulating layer 105. The first conductive layer 111 may be disposed between the first active pattern 101 and the bottom surface of the lowermost nanosheet of the first plurality of bottom nanosheets BNW1. The first conductive layer 111 may be disposed between adjacent first plurality of bottom nanosheets BNW1. The first conductive layer 111 may be disposed between the upper surface of the uppermost nanosheet of the first plurality of bottom nanosheets BNW1 and the bottom surface of the first nanosheet isolation layer NS1. For example, the first conductive layer 111 may surround the first plurality of bottom nanosheets BNW1. The first conductive layer 111 may be disposed on both sidewalls of the first nanosheet isolation layer NS1 in the second horizontal direction DR2. For example, the first conductive layer 111 may be formed in a liner shape.

The first filling conductive layer 121 may be disposed on the first conductive layer 111. The first filling conductive layer 121 may be disposed between the upper surface of the first nanosheet isolation layer NS1 and the bottom surface of the lowermost nanosheet of the first plurality of upper nanosheets UNW1. The first filling conductive layer 121 may surround the first plurality of upper nanosheets UNW1. The first filling conductive layer 121 may be disposed between the first gate spacers 131 on the upper surface of the uppermost nanosheet of the first plurality of upper nanosheets UNW1.

For example, the second gate electrode G2 may include a second conductive layer 112 and a second filling conductive layer 122. The second conductive layer 112 may be disposed on the upper surface of the field insulating layer 105. The second conductive layer 112 may be disposed between the second active pattern 102 and the bottom surface of the lowermost nanosheet of the second plurality of bottom nanosheets BNW2. The second conductive layer 112 may be disposed between adjacent second plurality of bottom nanosheets BNW2. The second conductive layer 112 may be disposed between the upper surface of the uppermost nanosheet of the second plurality of bottom nanosheets BNW2 and the bottom surface of the second nanosheet isolation layer NS2. For example, the second conductive layer 112 may surround the second plurality of bottom nanosheets BNW2. The second conductive layer 112 may be disposed on both sidewalls of the second nanosheet isolation layer NS2 in the second horizontal direction DR2. For example, the second conductive layer 112 may be formed in a liner shape. The second conductive layer 112 may be spaced apart from the first conductive layer 111 in the second horizontal direction DR2 on the upper surface of the field insulating layer 105.

The second filling conductive layer 122 may be disposed on the second conductive layer 112. The second filling conductive layer 122 may be disposed between the upper surface of the second nanosheet isolation layer NS2 and the bottom surface of the lowermost nanosheet of the second plurality of upper nanosheets UNW2. The second filling conductive layer 122 may surround the second plurality of upper nanosheets UNW2. The second filling conductive layer 122 may be disposed between the second gate spacers 132 on the upper surface of the uppermost nanosheet of the second plurality of upper nanosheets UNW2. The second filling conductive layer 122 may be spaced apart from the first filling conductive layer 121 in the second horizontal direction DR2 on the upper surface of the field insulating layer 105.

For example, each of the first and second conductive layers 111, 112 may include titanium aluminum nitride (TiAlN). In FIG. 4, each of the first and second filling conductive layers 121, 122 is shown as being formed as a single layer, but this is for convenience of explanation only and the present disclosure is not intended to be limited thereto. For example, each of the first and second filling conductive layers 121, 122 may be formed as multiple layers. For example, each of the first and second filling conductive layers 121, 122 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof.

The first gate spacer 131 may be disposed on both sidewalls of the first gate electrode G1 in the first horizontal direction DR1 on the upper surface of the uppermost nanosheet of the first plurality of upper nanosheets UNW1 and on the upper surface of the field insulating layer 105. The first gate spacer 131 may extend in the second horizontal direction DR2. The second gate spacer 132 may be disposed on both sidewalls of the second gate electrode G2 in the first horizontal direction DR1 on the upper surface of the uppermost nanosheet of the second plurality of upper nanosheets UNW2 and on the upper surface of the field insulating layer 105. The second gate spacer 132 may extend in the second horizontal direction DR2. The second gate spacer 132 may be spaced apart from the first gate spacer 131 in the second horizontal direction DR2. For example, each of the first and second gate spacers 131, 132 may include at least one of silicon nitride (SiN), silicon oxynitride (SiON), silicon carbonitride (SiCN), silicon oxycarbonitride (SiOCN), silicon boron nitride (SiBN), silicon oxyboron nitride (SiOBN), silicon oxycarbide (SiOC), and combinations thereof. However, the present disclosure is not limited thereto.

The bottom source/drain regions BSD may be disposed on both sidewalls of the first plurality of bottom nanosheets BNW1 in the first horizontal direction DR1 on the upper surface of the first active pattern 101. The bottom source/drain region BSD may be in contact with both sidewalls of the first plurality of bottom nanosheets BNW1 in the first horizontal direction DR1. The upper source/drain region USD may be disposed on both sidewalls of the first plurality of upper nanosheets UNW1 in the first horizontal direction DR1 on the upper surface of the bottom source/drain region BSD. The upper source/drain region USD may be in contact with both sidewalls of the first plurality of upper nanosheets UNW1 in the first horizontal direction DR1. The upper source/drain region USD may be spaced apart from the bottom source/drain region BSD in the vertical direction DR3.

The first gate insulating layer 141 may be disposed between the first gate electrode G1 and the first active pattern 101. The first gate insulating layer 141 may be disposed between the first gate electrode G1 and the field insulating layer 105. The first gate insulating layer 141 may be disposed between the first gate electrode G1 and the first plurality of bottom nanosheets BNW1. The first gate insulating layer 141 may be disposed between the first gate electrode G1 and the first nanosheet isolation layer NS1. The first gate insulating layer 141 may be disposed between the first gate electrode G1 and the first plurality of upper nanosheets UNW1. The first gate insulating layer 141 may be disposed between the first gate electrode G1 and the bottom source/drain region BSD. The first gate insulating layer 141 may be disposed between the first gate electrode G1 and the upper source/drain region USD. The first gate insulating layer 141 may be disposed between the first gate electrode G1 and the first gate spacer 131.

The second gate insulating layer 142 may be disposed between the second gate electrode G2 and the second active pattern 102. The second gate insulating layer 142 may be disposed between the second gate electrode G2 and the field insulating layer 105. The second gate insulating layer 142 may be disposed between the second gate electrode G2 and the second plurality of bottom nanosheets BNW2. The second gate insulating layer 142 may be disposed between the second gate electrode G2 and the second nanosheet isolation layer NS2. The second gate insulating layer 142 may be disposed between the second gate electrode G2 and the second plurality of upper nanosheets UNW2. The second gate insulating layer 142 may be disposed between the second gate electrode G2 and the second gate spacer 132.

Each of the first and second gate insulating layers 141, 142 may include at least one of silicon oxide, silicon oxynitride, silicon nitride, or a high-k dielectric material having a dielectric constant greater than that of silicon oxide. High-k dielectric materials may include, for example, one or more of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some other example embodiments may include an NC (Negative Capacitance) FET utilizing a negative capacitor. For example, each of the first and second gate insulating layers 141, 142 may include a ferroelectric material layer having ferroelectric properties and a paraelectric material layer having paraelectric properties.

The ferroelectric material layer may exhibit negative capacitance, while the paraelectric material layer may exhibit positive capacitance. For example, when two or more capacitors are connected in series and each of their capacitances has a positive value, the overall capacitance decreases relative to the capacitance of each individual capacitor. On the other hand, if the capacitances of at least one of the two or more capacitors connected in series has a negative value, the overall capacitance may be greater than the absolute value of each individual capacitance while still being positive.

When the ferroelectric material layer with negative capacitance and the paraelectric material layer with positive capacitance are connected in series, the overall capacitance value of the ferroelectric material layer and the paraelectric material layer connected in series may increase. By utilizing the increase in overall capacitance value, the transistor including the ferroelectric material layer may have a subthreshold swing (SS) of less than 60 mV/decade at room temperature.

The ferroelectric material layer may have ferroelectric properties. The ferroelectric material layer may include, for example, at least one of hafnium oxide, hafnium zirconium oxide, barium strontium titanium oxide, barium titanium oxide, and lead zirconium titanium oxide. As another example, hafnium zirconium oxide may be a material in which zirconium (Zr) is doped into hafnium oxide. In another example, hafnium zirconium oxide may be a compound of hafnium (Hf) and zirconium (Zr) with oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). Depending on which ferroelectric material the ferroelectric material layer contains, the type of dopant contained in the ferroelectric material layer may vary.

If the ferroelectric material layer includes hafnium oxide, the dopant included in the ferroelectric material layer may include, for example, at least one of gadolinium (Gd), silicon (Si), zirconium (Zr), aluminum (Al), and yttrium (Y).

If the dopant is aluminum (Al), the ferroelectric material layer may contain aluminum in a concentration of about 3 to 8 at % (atomic %). Here, the ratio of the dopant may be a ratio of aluminum relative to the sum of hafnium and aluminum.

If the dopant is silicon (Si), the ferroelectric material layer may contain 2 to 10 at % of silicon. If the dopant is yttrium (Y), the ferroelectric material layer may contain 2 to 10 at % of yttrium. If the dopant is gadolinium (Gd), the ferroelectric material layer may contain 1 to 7 at % of gadolinium. If the dopant is zirconium (Zr), the ferroelectric material layer may contain 50 to 80 at % of zirconium.

The paraelectric material layer may have paraelectric properties. The paraelectric material layer may include, for example, at least one of silicon oxide and a high-k metal oxide. The metal oxide included in the paraelectric material layer may include, for example, at least one of hafnium oxide, zirconium oxide, and aluminum oxide, but is not limited thereto.

The ferroelectric material layer and the paraelectric material layer may include the same material. While the ferroelectric material layer may have ferroelectric properties, the paraelectric material layer may not have ferroelectric properties. For example, if the ferroelectric material layer and the paraelectric material layer contain hafnium oxide, the crystal structure of the hafnium oxide included in the ferroelectric material layer is different from the crystal structure of the hafnium oxide included in the paraelectric material layer.

The ferroelectric material layer may have a thickness having ferroelectric properties. For example, the thickness of the ferroelectric material layer may range from 0.5 to 10 nm, but is not limited thereto. Since each ferroelectric material may have a different critical thickness for exhibiting ferroelectric properties, the thickness of the ferroelectric material layer may vary depending on the specific ferroelectric material.

For example, each of the first and second gate insulating layers 141, 142 may include a single ferroelectric material layer. In some example embodiments, each of the first and second gate insulating layers 141, 142 may include a plurality of ferroelectric material layers spaced apart from each other. Each of the first and second gate insulating layers 141, 142 may have a stacked layer structure in which the plurality of ferroelectric material layers are alternately stacked with the plurality of paraelectric material layers.

The first interlayer insulating layer 165 may cover each of the bottom source/drain region BSD and the upper source/drain region USD on the first and second active patterns 101, 102, and the field insulating layer 105. For example, the first interlayer insulating layer 165 may be disposed between the upper surface of the bottom source/drain region BSD and the bottom surface of the upper source/drain region USD. For example, the first interlayer insulating layer 165 may be disposed on both sidewalls in the first horizontal direction DR1 of each of the first nanosheet isolation layer NS1 and the first gate spacer 131.

For example, the first interlayer insulating layer 165 may include at least one of silicon oxide, silicon nitride, silicon oxynitride, and a low-k dielectric material. The low-k dielectric material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylCycloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica, and combinations thereof, but the present disclosure is not limited thereto.

The first etching stop layer 160 may be disposed between the first interlayer insulating layer 165 and the field insulating layer 105. The first etching stop layer 160 may be disposed between the first interlayer insulating layer 165 and the bottom source/drain region BSD. The first etching stop layer 160 may be disposed between the first interlayer insulating layer 165 and the upper source/drain region USD. The first etching stop layer 160 may be disposed between the first interlayer insulating layer 165 and the sidewall of the first nanosheet isolation layer NS1 in the first horizontal direction DR1. The first etching stop layer 160 may be disposed between the first interlayer insulating layer 165 and the sidewall of the first gate spacer 131 in the first horizontal direction DR1. For example, the first etching stop layer 160 may include at least one of aluminum oxide, aluminum nitride, hafnium oxide, zirconium oxide, silicon oxide, silicon nitride, silicon oxynitride, and low-k dielectric materials.

The first capping pattern 151 may extend in the second horizontal direction DR2 on the upper surface of each of the first gate spacer 131, the first gate insulating layer 141, and the first gate electrode G1. The second capping pattern 152 may extend in the second horizontal direction DR2 on the upper surface of each of the second gate spacer 132, the second gate insulating layer 142, and the second gate electrode G2. For example, the second capping pattern 152 may be spaced apart from the first capping pattern 151 in the second horizontal direction DR2. For example, the bottom surface of each of the first and second capping patterns 151, 152 may be in contact with the first etching stop layer 160. However, the present disclosure is not limited thereto. For example, the upper surface of each of the first and second capping patterns 151, 152 may be formed on the same plane as the upper surface of the first interlayer insulating layer 165. For example, each of the first and second capping patterns 151, 152 may include at least one of silicon nitride (SiN), silicon oxynitride (SiON), silicon oxide (SiO₂), silicon carbonitride (SiCN), silicon oxycarbonitride (SiOCN), and combinations thereof. However, the present disclosure is not limited thereto.

The gate cut 170 may extend in the first horizontal direction DR1 between the first active pattern 101 and the second active pattern 102. The gate cut 170 may be disposed between the first plurality of bottom nanosheets BNW1 and the second plurality of bottom nanosheets BNW2. The gate cut 170 may be disposed between the first nanosheet isolation layer NS1 and the second nanosheet isolation layer NS2. The gate cut 170 may be disposed between the first plurality of upper nanosheets UNW1 and the second plurality of upper nanosheets UNW2. The gate cut 170 may extend in the vertical direction DR3 on the upper surface of the substrate 100. For example, at least a portion of the gate cut 170 may be disposed inside the field insulating layer 105. For example, the bottom surface of the gate cut 170 may be in contact with the field insulating layer 105. For example, the upper surface of the gate cut 170 may be formed on the same plane as the upper surface of each of the first and second capping patterns 151, 152.

For example, the gate cut 170 may separate the first gate spacer 131 and the second gate spacer 132 in the second horizontal direction DR2. The gate cut 170 may separate the first gate electrode G1 and the second gate electrode G2 in the second horizontal direction DR2. The gate cut 170 may separate the first gate insulating layer 141 and the second gate insulating layer 142 in the second horizontal direction DR2. The gate cut 170 may separate the first capping pattern 151 and the second capping pattern 152 in the second horizontal direction DR2. For example, both sidewalls of the gate cut 170 in the second horizontal direction DR2 may be in contact with the first and second gate spacers 131, 132. Both sidewalls of the gate cut 170 in the second horizontal direction DR2 can be in contact with the first and second gate electrodes G1, G2. Both sidewalls of the gate cut 170 in the second horizontal direction DR2 may be in contact with the first and second gate insulating layers 141, 142. Both sidewalls of the gate cut 170 in the second horizontal direction DR2 may be in contact with the field insulating layer 105. Both sidewalls of the gate cut 170 in second horizontal direction DR2 may be in contact with first and second capping patterns 151, 152.

For example, the width W2 of the gate cut 170 in the second horizontal direction DR2 between the first and second gate spacers 131, 132 is greater than the width W1 of the gate cut 170 in the second horizontal direction DR2 between the first and second gate electrodes G1, G2. For example, the gate cut 170 may include at least one of silicon nitride (SiN), silicon oxynitride (SiON), silicon carbonitride (SiCN), silicon oxycarbonitride (SiOCN), silicon boron nitride (SiBN), silicon oxyboron nitride (SiOBN), silicon oxycarbide (SiOC), and combinations thereof.

For example, the gate cut 170 may include a first portion 171 and a second portion 172 disposed on the upper surface of the first portion 171. For example, at least a portion of the first portion 171 of the gate cut 170 may be disposed inside the field insulating layer 105. The bottom surface of the first portion 171 of the gate cut 170 may be in contact with the field insulating layer 105. The first portion 171 of the gate cut 170 may be disposed between the first active pattern 101 and the second active pattern 102. The first portion 171 of the gate cut 170 may separate the first gate insulating layer 141 and the second gate insulating layer 142 in the second horizontal direction DR2. The first portion 171 of the gate cut 170 may separate the first conductive layer 111 and the second conductive layer 112 in the second horizontal direction DR2.

For example, both sidewalls of the first portion 171 of the gate cut 170 in the second horizontal direction DR2 may be in contact with the field insulating layer 105. Both sidewalls of the first portion 171 of the gate cut 170 in the second horizontal direction DR2 may be in contact with the first and second gate insulating layers 141, 142. Both sidewalls of the gate cut 170 of the first portion 171 in the second horizontal direction DR2 may be in contact with the first and second conductive layers 111, 112. For example, the upper surface of the first portion 171 of the gate cut 170 may be formed on the same plane as the upper surface of each of the first and second conductive layers 111, 112 disposed on the field insulating layer 105. For example, at least a portion of the upper surface of the first portion 171 of the gate cut 170 may be in contact with the first and second gate electrodes G1, G2. For example, at least a portion of the upper surface of the first portion 171 of the gate cut 170 may be in contact with the first and second filling conductive layers 121, 122.

For example, the second portion 172 of the gate cut 170 may extend in the vertical direction DR3 on the first portion 171 of the gate cut 170. The second portion 172 of the gate cut 170 may be formed integrally with the first portion 171 of the gate cut 170. For example, the second portion 172 of the gate cut 170 may be disposed between the first plurality of bottom nanosheets BNW1 and the second plurality of bottom nanosheets BNW2. The second portion 172 of the gate cut 170 may be disposed between the first nanosheet isolation layer NS1 and the second nanosheet isolation layer NS2. The second portion 172 of the gate cut 170 may be disposed between the first plurality of upper nanosheets UNW1 and the second plurality of upper nanosheets UNW2. For example, both sidewalls of the second portion 172 of the gate cut 170 in the second horizontal direction DR2 may have a continuous slope profile (e.g., a continuous sloped profile).

For example, the bottom surface of the second portion 172 of the gate cut 170 may be in contact with the upper surface of the first portion 171 of the gate cut 170. The second portion 172 of the gate cut 170 may separate the first filling conductive layer 121 and the second filling conductive layer 122 in the second horizontal direction DR2. The second portion 172 of the gate cut 170 may separate the first capping pattern 151 and the second capping pattern 152 in the second horizontal direction DR2. For example, both sidewalls of the second portion 172 of the gate cut 170 in the second horizontal direction DR2 may be in contact with the first and second filling conductive layers 121, 122. Both sidewalls of the second portion 172 of the gate cut 170 in the second horizontal direction DR2 may be in contact with the first and second capping patterns 151, 152.

For example, the upper surface of the second portion 172 of the gate cut 170 may be formed on the same plane as the upper surface of each of the first and second capping patterns 151, 152. For example, the width of the upper surface of the first portion 171 of the gate cut 170 in the second horizontal direction DR2 is greater than the width W3 of the bottom surface of the second portion 172 of the gate cut 170 in the second horizontal direction DR2. For example, the width W3 of the bottom surface of the second portion 172 of the gate cut 170 in the second horizontal direction DR2 is greater than the width W4 of the upper surface of the second portion 172 of the gate cut 170 in the second horizontal direction DR2. For example, the distance in the second horizontal direction DR2 between the first plurality of bottom nanosheets BNW1 and the second portion 172 of the gate cut 170 is greater than the distance in the second horizontal direction DR2 between the first active pattern 101 and the first portion 171 of the gate cut 170. Further, the distance in the second horizontal direction DR2 between the second plurality of bottom nanosheets BNW2 and the second portion 172 of the gate cut 170 is greater than the distance in the second horizontal direction DR2 between the second active pattern 102 and the first portion 171 of the gate cut 170.

The first source/drain contact CA1 may be disposed on the first side of the first gate electrode G1. The first source/drain contact CA1 may be disposed over the upper source/drain region USD disposed on the first side of the first gate electrode G1. The first source/drain contact CA1 may penetrate the first interlayer insulating layer 165 and the first etching stop layer 160 in the vertical direction DR3 to be electrically connected to the upper source/drain region USD disposed on the first side of the first gate electrode G1. The second source/drain contact CA2 may be disposed on the second side of the first gate electrode G1 opposite the first side of the first gate electrode G1 in the first horizontal direction DR1. The second source/drain contact CA2 may be disposed over the upper source/drain region USD disposed on the second side of the first gate electrode G1. The second source/drain contact CA2 may penetrate the first interlayer insulating layer 165 and the first etching stop layer 160 in the vertical direction DR3 to be electrically connected to the upper source/drain region USD disposed on the second side of the first gate electrode G1.

For example, the upper surface of each of the first and second source/drain contacts CA1, CA2 may be formed on the same plane as the upper surface of the first interlayer insulating layer 165. In FIG. 2, each of the first and second source/drain contacts CA1, CA2 is shown to be formed as a single layer, but the present disclosure is not limited thereto. In some other example embodiments, each of the first and second source/drain contacts CA1, CA2 may be formed as multiple layers. Each of the first and second source/drain contacts CA1, CA2 may include a conductive material.

The silicide layer SL may be disposed along the interface between the upper source/drain region USD disposed on the first side of the first gate electrode G1 and the first source/drain contact CA1. Further, the silicide layer SL may be disposed along the interface between the upper source/drain region USD disposed on the second side of the first gate electrode G1 and the second source/drain contact CA2. For example, the silicide layer SL may include a metal silicide material.

The first gate contact CB1 may penetrate the first capping pattern 151 in the vertical direction DR3 to connect to the first gate electrode G1. The second gate contact CB2 may penetrate the second capping pattern 152 in the vertical direction DR3 to connect to the second gate electrode G2. For example, the upper surface of each of the first and second gate contacts CB1, CB2 may be formed on the same plane as the upper surface of each of the first and second capping patterns 151, 152. However, the present disclosure is not limited thereto. In some example embodiments, the upper surface of each of the first and second gate contacts CB1, CB2 may be formed higher than the upper surface of each of the first and second capping patterns 151, 152. In FIGS. 2 and 4, each of the first and second gate contacts CB1, CB2 is shown to be formed as a single layer, but the present disclosure is not limited thereto. In some example embodiments, each of the first and second gate contacts CB1, CB2 may be formed as multiple layers. Each of the first and second gate contacts CB1, CB2 may include a conductive material.

The second etching stop layer 180 may be disposed on the upper surface of each of the first interlayer insulating layer 165, the first and second capping patterns 151, 152, the first and second gate contacts CB1, CB2, the first and second source/drain contacts CA1, CA2, and the gate cut 170. For example, the second etching stop layer 180 may be conformally formed. In FIGS. 2 to 4, the second etching stop layer 180 is shown as being formed as a single layer, but the present disclosure is not limited thereto. In some example embodiments, the second etching stop layer 180 may be formed as multiple layers. For example, the second etching stop layer 180 may include at least one of aluminum oxide, aluminum nitride, hafnium oxide, zirconium oxide, silicon oxide, silicon nitride, silicon oxynitride, and a low-k dielectric material.

The second interlayer insulating layer 185 may be disposed on the second etching stop layer 180. For example, the second interlayer insulating layer 185 may include at least one of silicon oxide, silicon nitride, silicon oxynitride, and low-k dielectric materials. The first via V1 may penetrate the second interlayer insulating layer 185 and the second etching stop layer 180 in the vertical direction DR3 to be connected to the first gate contact CB1. The second via V2 may penetrate the second interlayer insulating layer 185 and the second etching stop layer 180 in the vertical direction DR3 to be connected to the second gate contact CB2. Each of the first and second vias V1, V2 may include a conductive material.

For example, the first plurality of bottom nanosheets BNW1, the first gate electrode G1, and the bottom source/drain region BSD may form a PMOS transistor. The second plurality of bottom nanosheets BNW2, the second gate electrode G2, and the bottom source/drain region BSD may form a PMOS transistor. For example, the first plurality of upper nanosheets UNW1, the first gate electrode G1, and the upper source/drain region USD may form an NMOS transistor. The second plurality of upper nanosheets UNW2, the second gate electrode G2, and the upper source/drain region USD may form an NMOS transistor.

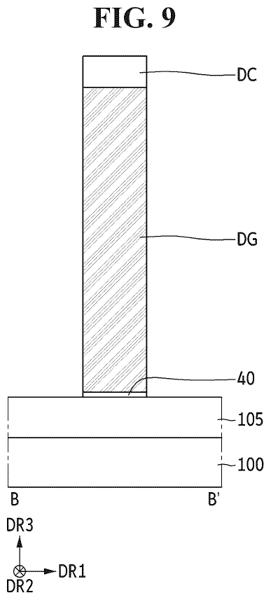

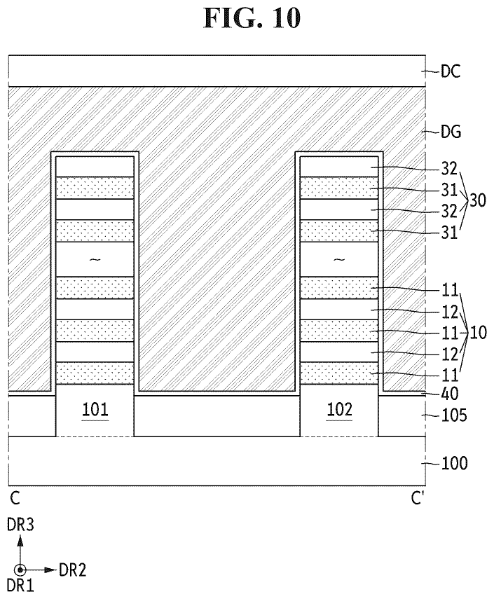

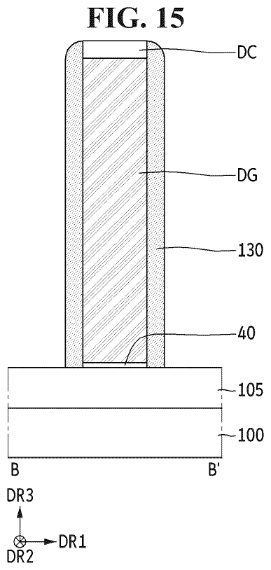

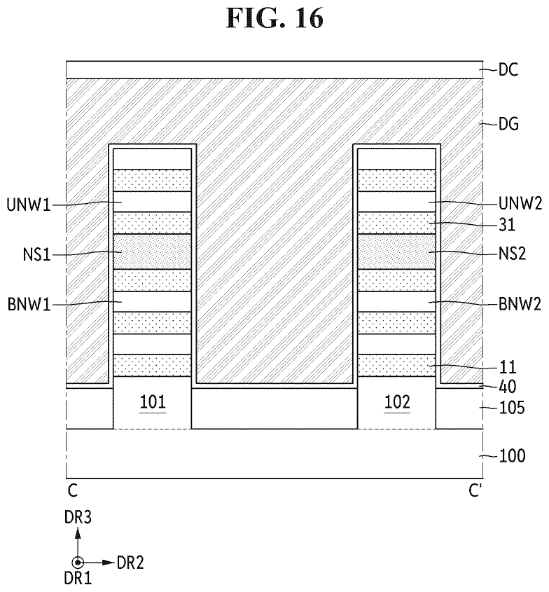

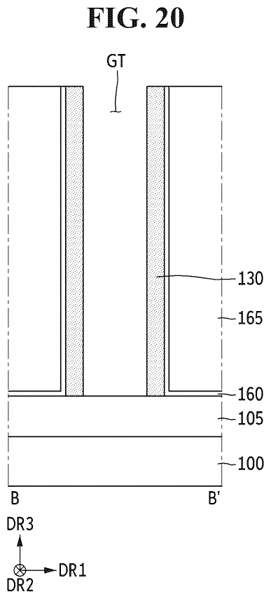

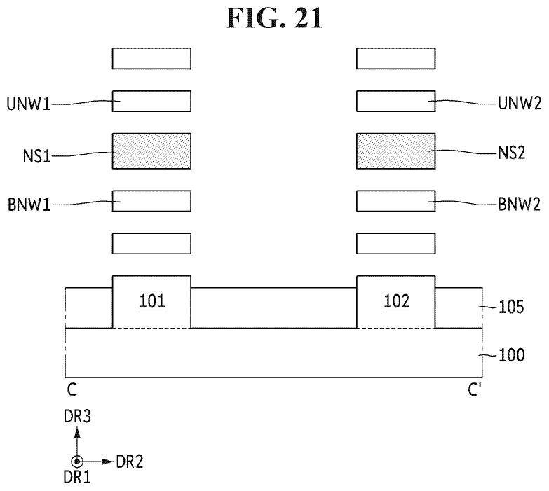

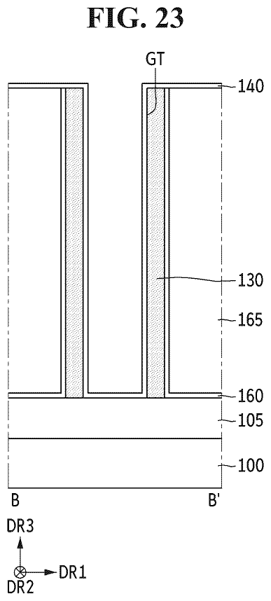

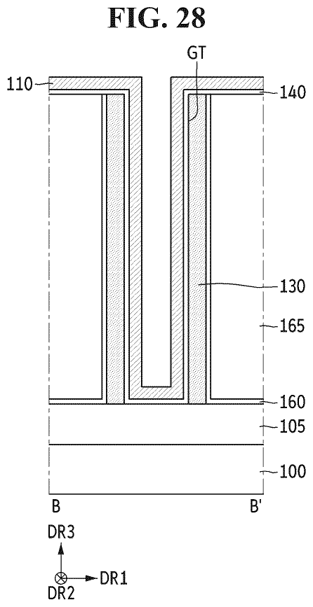

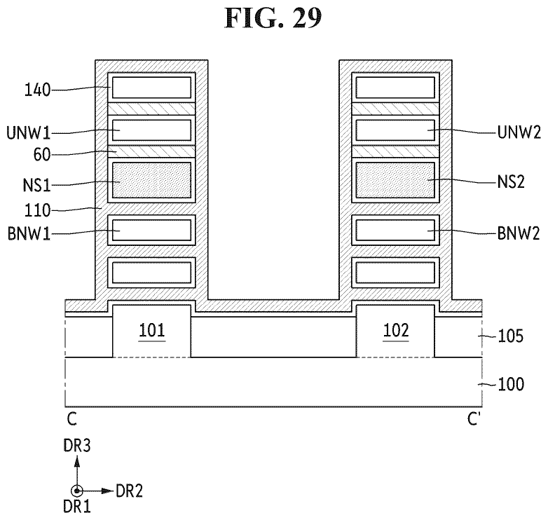

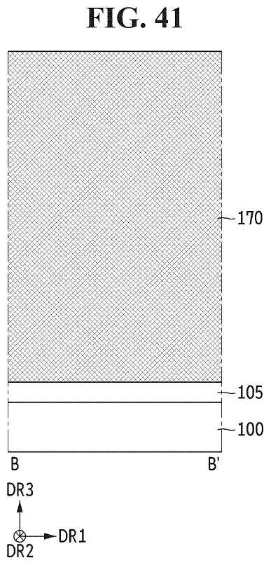

Hereinafter, a fabrication method of a semiconductor device according to some example embodiments of the present disclosure will be described with reference to FIGS. 2 to 46.

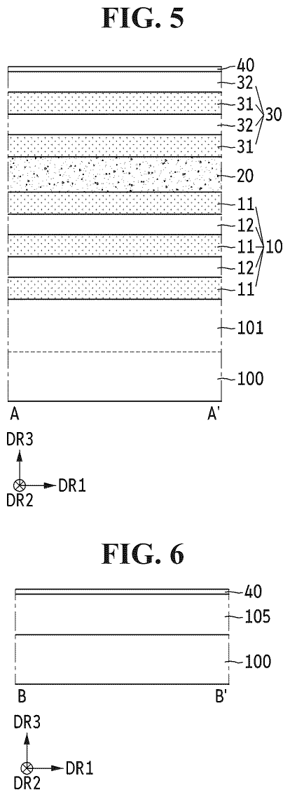

FIGS. 5 to 46 are intermediate stage diagrams for explaining a method of fabricating a semiconductor device according to some example embodiments of the present disclosure.

Referring to FIGS. 5 to 7, a first stacked structure 10, an isolation material layer 20, and a second stacked structure 30 may be sequentially stacked on the substrate 100. For example, the first stacked structure 10 may be formed on the substrate 100. The first stacked structure 10 may include a first semiconductor layer 11 and a second semiconductor layer 12 alternately stacked on the substrate 100. For example, the first semiconductor layer 11 may be formed on each of the lowermost and uppermost portions of the first stacked structure 10. For example, the isolation material layer 20 may be formed on the upper surface of the first stacked structure 10. For example, the second stacked structure 30 may include a third semiconductor layer 31 and a fourth semiconductor layer 32 alternately stacked on the upper surface of the isolation material layer 20. For example, the third semiconductor layer 31 may be formed at the lowermost portion of the second stacked structure 30, and the fourth semiconductor layer 32 may be formed at the uppermost portion of the second stacked structure 30.

For example, each of the first semiconductor layer 11 and the third semiconductor layer 31 may include silicon germanium (SiGe). For example, each of the second semiconductor layer 12 and the fourth semiconductor layer 32 may include silicon (Si). For example, the isolation material layer 20 may include silicon germanium (SiGe). For example, the concentration of germanium (Ge) in the isolation material layer 20 may be greater than the concentration of germanium (Ge) in each of the first semiconductor layer 11 and the third semiconductor layer 31.

Subsequently, a portion of each of the second stacked structure 30, the isolation material layer 20, and the first stacked structure 10 may be etched. After such an etching process is performed, the sidewalls of each of the remaining second stacked structure 30, the isolation material layer 20, and the first stacked structure 10 in the second horizontal direction DR2 may have a continuous sloped profile. While each of the second stacked structure 30, the isolation material layer 20, and the first stacked structure 10 is being etched, a portion of the substrate 100 may be etched. Accordingly, each of the first and second active patterns 101, 102 may be defined beneath the first stacked structure 10. Each of the first and second active patterns 101, 102 may extend in the first horizontal direction DR1. The second active pattern 102 may be spaced apart from the first active pattern 101 in the second horizontal direction DR2.

Subsequently, a field insulating layer 105 may be formed on the substrate 100 to surround the sidewalls of each of the first and second active patterns 101, 102. Subsequently, a pad oxide layer 40 may be formed to cover the field insulating layer 105, the exposed first and second active patterns 101, 102, the first stacked structure 10, the isolation material layer 20, and the second stacked structure 30. For example, the pad oxide layer 40 may be formed conformally. For example, the pad oxide layer 40 may include silicon oxide (SiO₂).

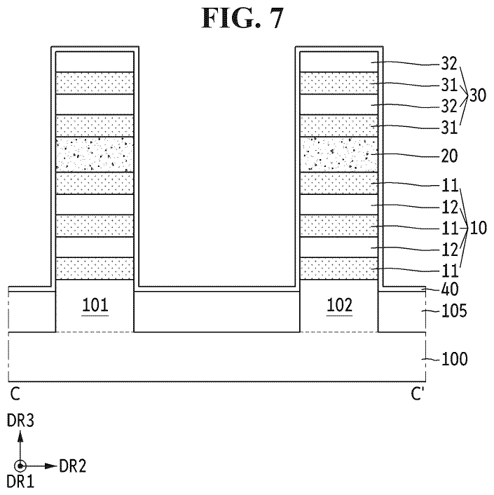

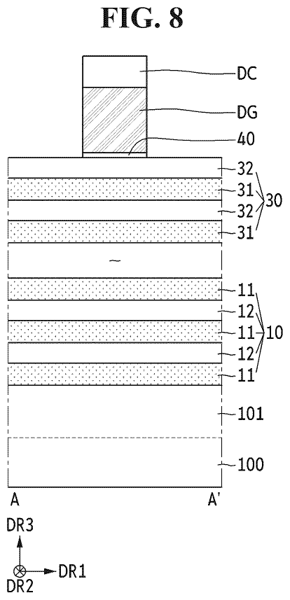

Referring to FIGS. 8 to 10, a dummy gate DG and a dummy capping pattern DC extending in the second horizontal direction DR2 on the field insulating layer 105 and the second stacked structure 30 may be formed. The dummy capping pattern DC may be formed on the upper surface of the dummy gate DG. For example, the pad oxide layer 40 of the remaining portion except the portion that overlaps with the dummy gate DG in the vertical direction DR3 may be removed. Subsequently, the isolation material layer 20 (see FIGS. 5 and 7) may be etched. For example, the isolation material layer 20 (see FIGS. 5 and 7) may be etched through a wet etching process.

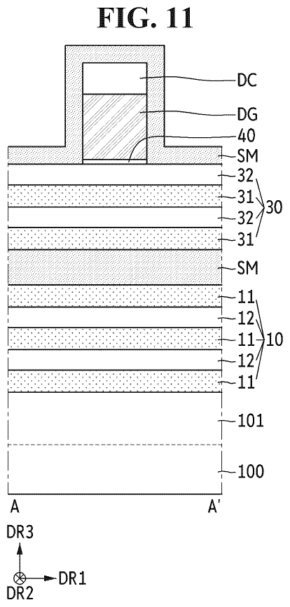

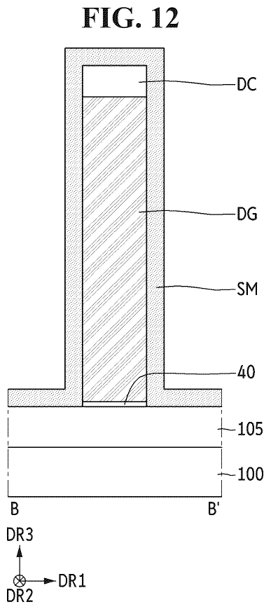

Referring to FIGS. 11 to 13, a spacer material layer SM may be formed to cover the sidewalls of the dummy gate DG, the sidewalls and upper surface of dummy capping pattern DC, and the upper surface of each of the first stacked structure 10, the second stacked structure 30, and the field insulating layer 105. The spacer material layer SM may fill the portion where the isolation material layer 20 (see FIGS. 5 and 7) is etched. For example, the spacer material layer SM may be formed conformally. For example, the spacer material layer SM may include at least one of silicon nitride (SiN), silicon oxynitride (SiON), silicon carbonitride (SiCN), silicon oxycarbonitride (SiOCN), silicon boron nitride (SiBN), silicon oxyboron nitride (SiOBN), silicon oxycarbide (SiOC), and combinations thereof.

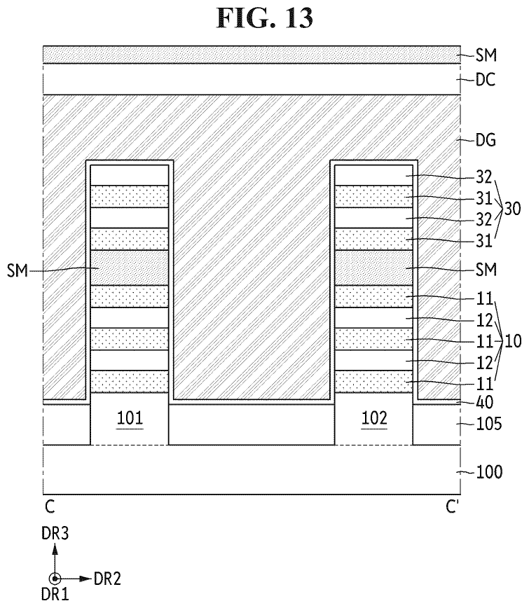

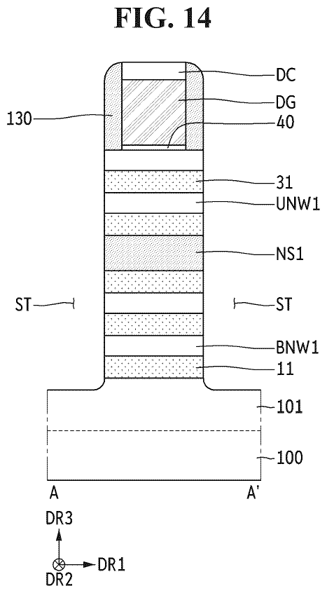

Referring to FIGS. 14 to 16, the first stacked structure 10 (see FIGS. 11 and 13), the spacer material layer SM (see FIGS. 11 to 13), and the second stacked structure 30 (see FIGS. 11 and 13) may be etched using the dummy capping pattern DC and the dummy gate DG as masks to form a source/drain trench ST. For example, the source/drain trench ST may be formed on both sides of the dummy gate DG in the first horizontal direction DR1 on the first active pattern 101. For example, the source/drain trench ST may extend into the inside of the first active pattern 101.

For example, while the source/drain trench ST is being formed, portions of the spacer material layer SM (see FIGS. 11 to 13) formed on the upper surface of the dummy capping pattern DC and the dummy capping pattern DC may be etched away. After the source/drain trench ST is formed, the spacer material layer SM (see FIGS. 11 to 13) remaining on both sidewalls of the first horizontal direction DR1 of each of the dummy gate DG and the dummy capping pattern DC may be defined as the gate spacer material layer 130.

For example, after the source/drain trench ST is formed, the second semiconductor layer 12 (see FIG. 13) remaining under the dummy gate DG may be defined as the first and second plurality of bottom nanosheets BNW1, BNW2. After the source/drain trench ST is formed, the fourth semiconductor layer 32 (see FIG. 13) remaining under the dummy gate DG may be defined as the first and second plurality of upper nanosheets UNW1, UNW2. Further, after the source/drain trench ST is formed, the spacer material layer SM (see FIGS. 11 to 13) remaining between the first semiconductor layer 11 and the third semiconductor layer 31 may be defined as the first and second nanosheet isolation layers NS1, NS2.

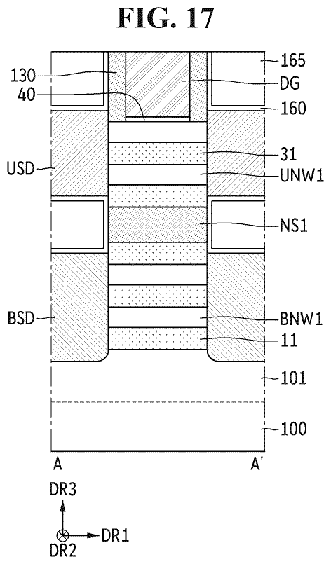

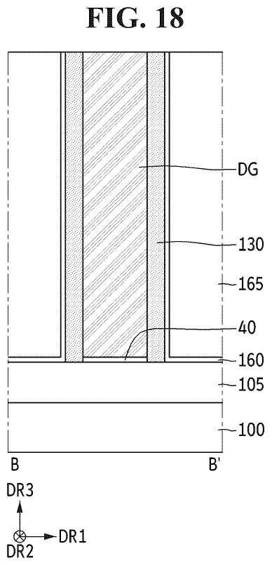

Referring to FIGS. 17 and 18, a bottom source/drain region BSD and an upper source/drain region USD may be formed inside the source/drain trench ST (see FIG. 14). For example, the bottom source/drain region BSD may be in contact with both sidewalls of the first plurality of bottom nanosheets BNW1 in the first horizontal direction DR1. The upper source/drain region USD may be in contact with both sidewalls of the first plurality of upper nanosheets UNW1 in the first horizontal direction DR1. The upper source/drain region USD may be spaced apart from the bottom source/drain region BSD in the vertical direction DR3.

For example, a first etching stop layer 160 and a first interlayer insulating layer 165 may be formed on the exposed surface of each of the field insulating layer 105, the bottom source/drain region BSD, the upper source/drain region USD, the first semiconductor layer 11, the third semiconductor layer 31, the first and second nanosheet isolation layers NS1, NS2, and the gate spacer material layer 130. The first interlayer insulating layer 165 may be formed on the first etching stop layer 160. For example, the first etching stop layer 160 may be conformally formed. Subsequently, a planarization process may be performed to expose the upper surface of the dummy gate DG.

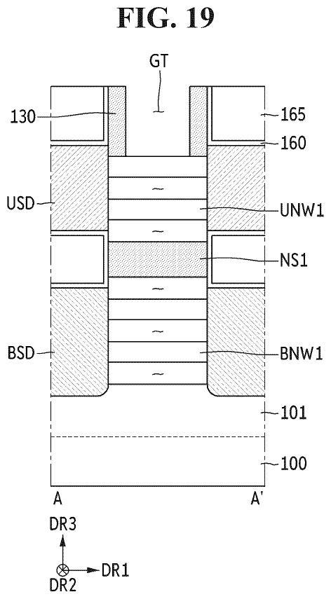

Referring to FIGS. 19 to 21, the dummy gate DG (see FIGS. 17 and 18), the pad oxide layer 40 (see FIGS. 17 and 18), the first semiconductor layer 11 (see FIG. 17), and the third semiconductor layer 31 (see FIG. 17) may each be etched. The portion in which each of the dummy gate DG (see FIGS. 17 and 18), the pad oxide layer 40 (see FIGS. 17 and 18), the first semiconductor layer 11 (see FIG. 17), and the third semiconductor layer 31 (see FIG. 17) is etched may be defined as a gate trench GT.

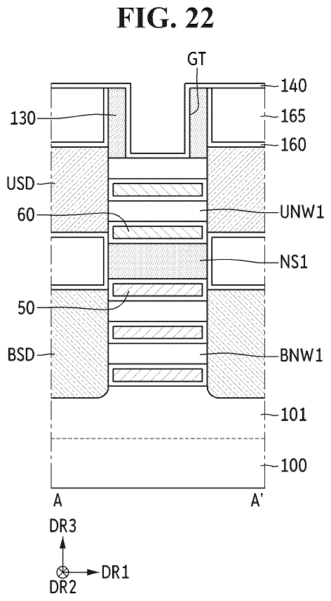

Referring to FIGS. 22 to 24, a gate insulating material layer 140 may be formed on the exposed surface through the gate trench GT. The gate insulating material layer 140 may be formed on the upper surface of each of the gate spacer material layer 130, the first etching stop layer 160, and the first interlayer insulating layer 165. For example, the gate insulating material layer 140 may be formed conformally. For example, the gate insulating material layer 140 may include at least one of silicon oxide, silicon oxynitride, silicon nitride, or a high-k dielectric material having a dielectric constant greater than that of silicon oxide.

Subsequently, a first sacrificial layer 50 may be formed between the upper surface of the first active pattern 101 and the bottom surface of the lowermost nanosheet of the first plurality of bottom nanosheets BNW1, between adjacent first plurality of bottom nanosheets BNW1, and between the upper surface of the uppermost nanosheet of the first plurality of bottom nanosheets BNW1 and the bottom surface of the first nanosheet isolation layer NS1, respectively. The first sacrificial layer 50 may be formed between the upper surface of the second active pattern 102 and the bottom surface of the lowermost nanosheet of the second plurality of bottom nanosheets BNW2, between adjacent second plurality of bottom nanosheets BNW2, and between the upper surface of the uppermost nanosheet of the second plurality of bottom nanosheets BNW2 and the bottom surface of the second nanosheet isolation layer NS2, respectively. For example, the first sacrificial layer 50 may include aluminum oxide (AlO).

Next, a second sacrificial layer 60 may be formed between the upper surface of the first nanosheet isolation layer NS1 and the bottom surface of the lowermost nanosheet of the first plurality of upper nanosheets UNW1, and between adjacent first plurality of upper nanosheets UNW1, respectively. Further, the second sacrificial layer 60 may be formed between the upper surface of the second nanosheet isolation layer NS2 and the bottom surface of the lowermost nanosheet of the second plurality of upper nanosheets UNW2, and between adjacent second plurality of upper nanosheets UNW2, respectively. For example, the second sacrificial layer 60 may include lanthanum oxide (LaO).

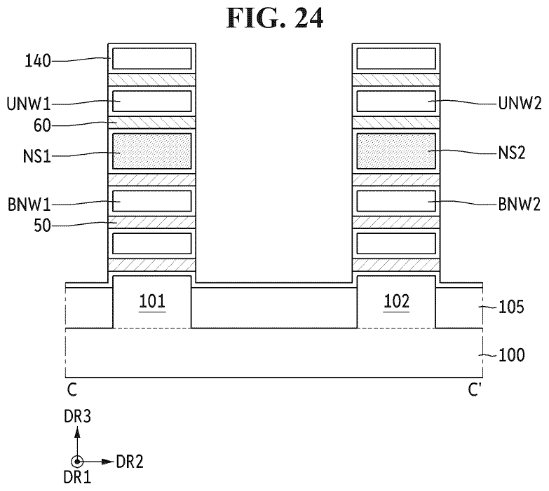

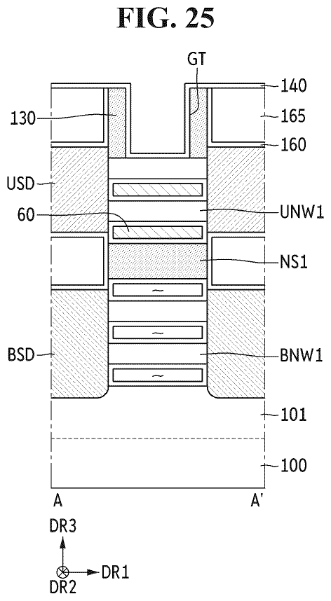

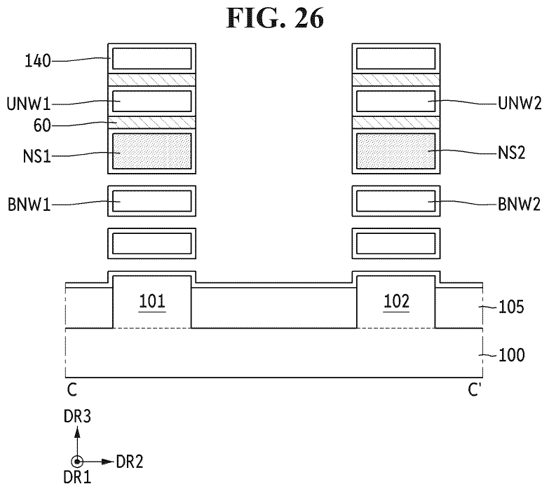

Referring to FIGS. 25 and 26, the first sacrificial layer 50 (see FIGS. 22 and 24) may be etched. For example, the first sacrificial layer 50 (see FIGS. 22 and 24) may be etched through a wet etching process.

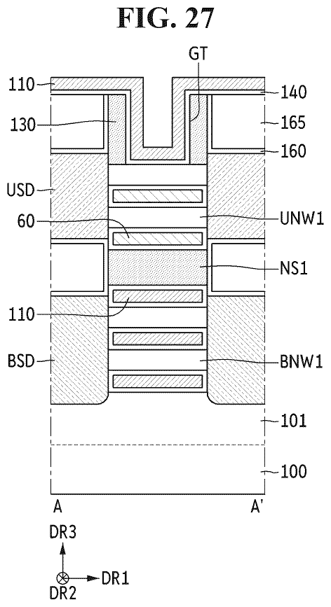

Referring to FIGS. 27 to 29, a conductive material layer 110 may be formed on the gate insulating material layer 140 inside the gate trench GT. For example, the conductive material layer 110 may fill each of the spaces between the upper surface of the first active pattern 101 and the bottom surface of the lowermost nanosheet of the first plurality of bottom nanosheets BNW1, between adjacent first plurality of bottom nanosheets BNW1, and between the upper surface of the uppermost nanosheet of the first plurality of bottom nanosheets BNW1 and the bottom surface of the first nanosheet isolation layer NS1. Further, the conductive material layer 110 may fill each of the spaces between the upper surface of the second active pattern 102 and the bottom surface of the lowermost nanosheet of the second plurality of bottom nanosheets BNW2, between adjacent second plurality of bottom nanosheets BNW2, and between the upper surface of the uppermost nanosheet of the second plurality of bottom nanosheets BNW2 and the bottom surface of the second nanosheet isolation layer NS2. For example, the conductive material layer 110 may be formed on the gate insulating material layer 140 formed on the upper surface of each of the gate spacer material layer 130, the first etching stop layer 160, and the first interlayer insulating layer 165. For example, the conductive material layer 110 may be formed conformally. For example, the conductive material layer 110 may include titanium aluminum nitride (TiAlN).

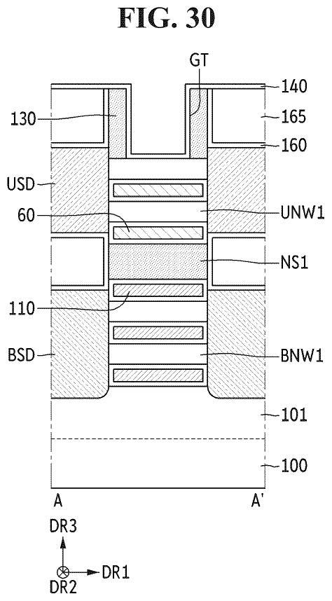

Referring to FIGS. 30 to 32, a first protective layer 70 may be formed on the conductive material layer 110. For example, the first protective layer 70 may include SOH (Spin On Hardmask). Subsequently, a portion of the first protective layer 70 may be etched. After a portion of the first protective layer 70 is etched, an upper surface of the remaining first protective layer 70 may be formed between the bottom surface of the first nanosheet isolation layer NS1 and the upper surface of the first nanosheet isolation layer NS1. Subsequently, the conductive material layer 110 exposed on the upper surface of the first protective layer 70 may be etched. For example, the uppermost surface of the remaining conductive material layer 110 may be formed between the bottom surface of the first nanosheet isolation layer NS1 and the upper surface of the first nanosheet isolation layer NS1.

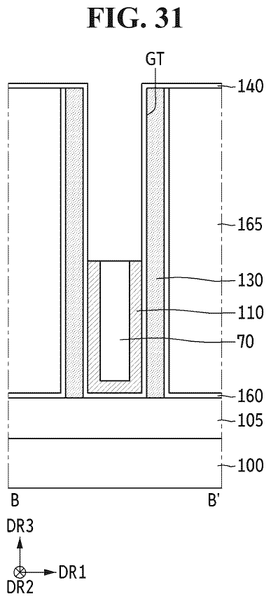

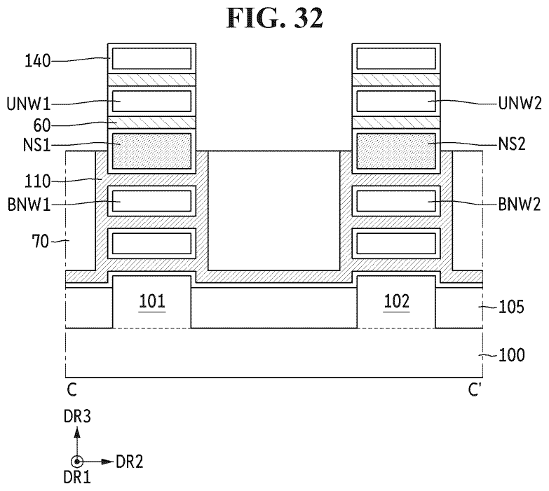

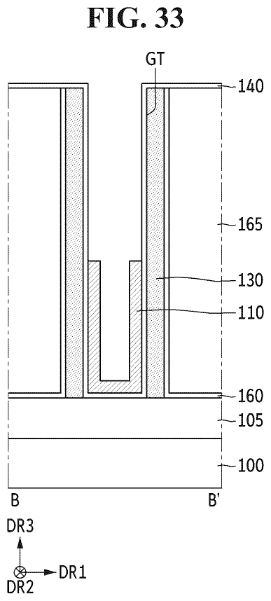

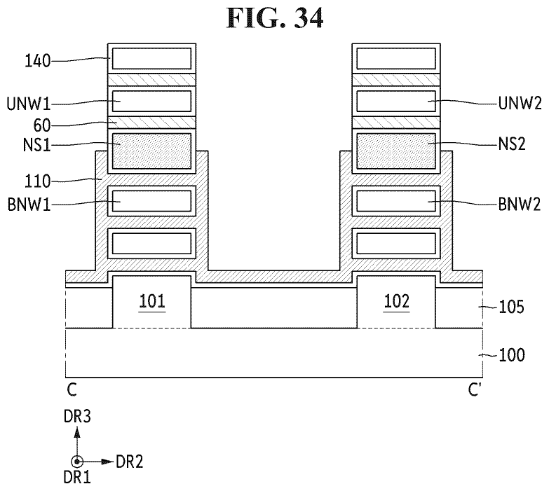

Referring to FIGS. 33 and 34, the first protective layer 70 (see FIGS. 31 and 32) may be etched.

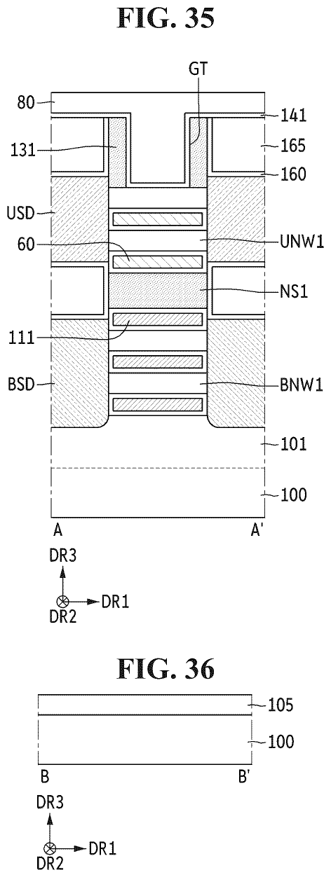

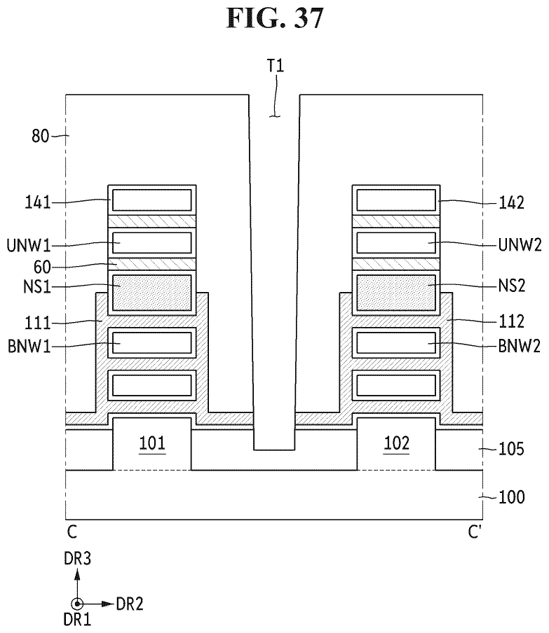

Referring to FIGS. 35 and 37, a second protective layer 80 may be formed to fill the inside of the gate trench GT. For example, the second protective layer 80 may be formed on the gate insulating material layer 140 (see FIG. 33) formed on the upper surface of each of the gate spacer material layer 130 (see FIG. 33), the first etching stop layer 160, and the first interlayer insulating layer 165. For example, the second protective layer 80 may include a material in which a material including carbon (C) may be selectively deposited. For example, the second protective layer 80 may include BARC (Bottom Anti-Reflective Coating) or SOH(Spin On Hardmask). However, the present disclosure is not limited thereto.

Subsequently, a first trench T1 may be formed between the first active pattern 101 and the second active pattern 102. For example, the first trench T1 may extend in the first horizontal direction DR1. For example, the first trench T1 may penetrate each of the second protection layer 80, the gate spacer material layer 130 (see FIG. 33), the conductive material layer 110 (see FIGS. 33 and 34), and the gate insulating material layer 140 (see FIGS. 33 and 34) in the vertical direction DR3 to extend into the inside of the field insulating layer 105. For example, the bottom surface of the first trench T1 may be defined by the field insulating layer 105. For example, the width of the upper surface of the first trench T1 in the second horizontal direction DR2 may be formed greater than the width of the bottom surface of the first trench T1 in the second horizontal direction DR2. For example, the sidewalls of the first trench T1 in the second horizontal direction DR2 may have a continuous slope profile.

For example, the first trench T1 may separate the gate spacer material layer 130 (see FIG. 33) in the second horizontal direction DR2. After the first trench T1 is formed, the remaining gate spacer material layer 130 (see FIG. 33) may be defined as a first gate spacer 131 and a second gate spacer 132 (see FIG. 1). For example, the first trench T1 may separate the conductive material layer 110 (see FIGS. 33 and 34) in the second horizontal direction DR2. After the first trench T1 is formed, the remaining conductive material layer 110 (see FIGS. 33 and 34) may be defined as a first conductive layer 111 and a second conductive layer 112. For example, the first trench T1 may separate the gate insulating material layer 140 (see FIGS. 33 and 34) in the second horizontal direction DR2. After the first trench T1 is formed, the remaining gate insulating material layer 140 (see FIGS. 33 and 34) may be defined as a first gate insulating layer 141 and a second gate insulating layer 142.

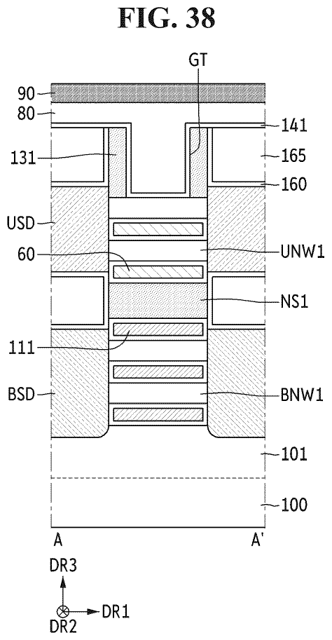

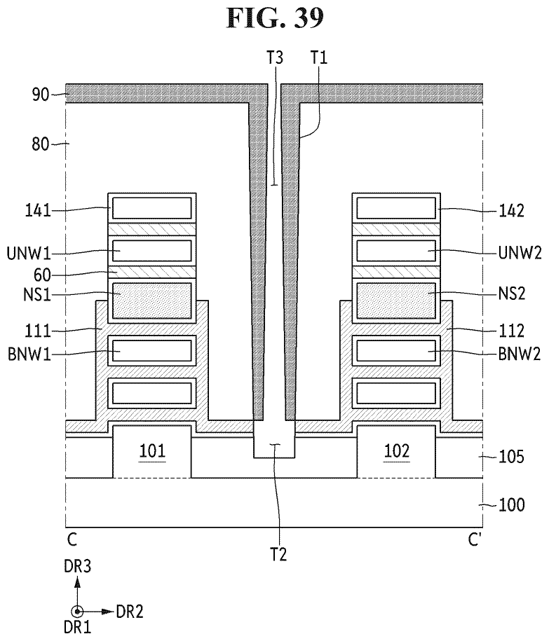

Referring to FIGS. 38 and 39, a liner layer 90 may be formed on the exposed surface of the second protective layer 80 along the sidewalls of the first trench T1. For example, the liner layer 90 may be formed only on the exposed surface of the second protective layer 80. The liner layer 90 may not be formed on the surface of each of the field insulating layer 105, the first and second gate insulating layers 141, 142, and the first and second conductive layers 111, 112, which are exposed through the first trench T1. For example, inside the first trench T1, each of the field insulating layer 105, the first and second gate insulating layers 141, 142, and the first and second conductive layers 111, 112 may be exposed on the bottom surface of the liner layer 90.

For example, the thickness of the liner layer 90 formed on the sidewalls of the first trench T1 in the second horizontal direction DR2 may increase continuously as it approaches the upper surface of the second protective layer 80. This is because, during the formation of the liner layer 90, the liner layer 90 formed on the upper sidewalls of the first trench T1 is formed thicker than the liner layer 90 formed on the lower sidewalls of the first trench T1. After the liner layer 90 is formed, the region formed on the bottom surface of the liner layer 90 may be defined as the second trench T2. For example, after the liner layer 90 is formed, the region formed between the liner layers 90 inside of the first trench T1 may be defined as a third trench T3. For example, the width of the third trench T3 in the second horizontal direction DR2 may increase continuously as it approaches the bottom surface of the second protective layer 80.

For example, the liner layer 90 may include a material that is selectively deposited only on the surface of the second protective layer 80. For example, the liner layer 90 may include carbon (C). In some example embodiments, the liner layer 90 may include BARC (Bottom Anti-Reflective Coating) or SOH (Spin On Hardmask). In some example embodiments, the liner layer 90 may include silicon carbide (SiC) or silicon oxycarbide (SiOC).

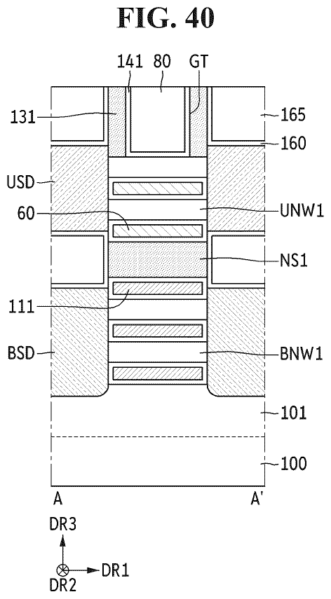

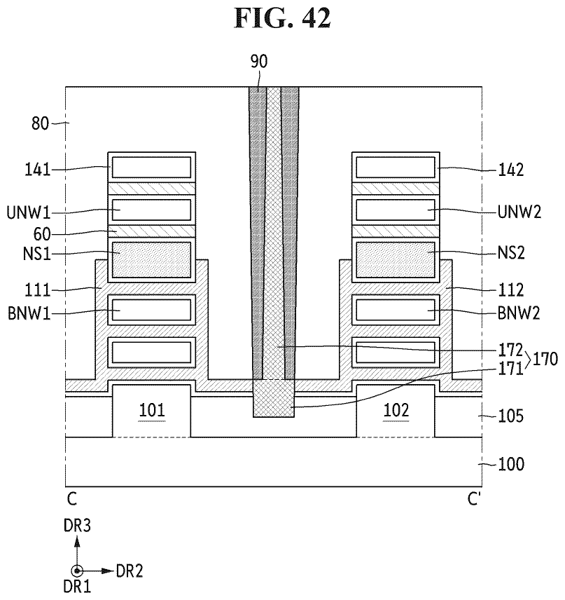

Referring now to FIGS. 40 and 42, a gate cut 170 may be formed inside each of the second trench T2 (see FIG. 39) and the third trench T3 (see FIG. 39). For example, a portion of the gate cut 170 formed inside the second trench T2 (see FIG. 39) may be defined as a first portion 171 of the gate cut 170. Further, the remaining portion of the gate cut 170 formed inside the third trench T3 (see FIG. 39) may be defined as a second portion 172 of the gate cut 170. Subsequently, a planarization process may be performed to expose the upper surface of each of the first etching stop layer 160, the first interlayer insulating layer 165, and the first gate spacer 131.

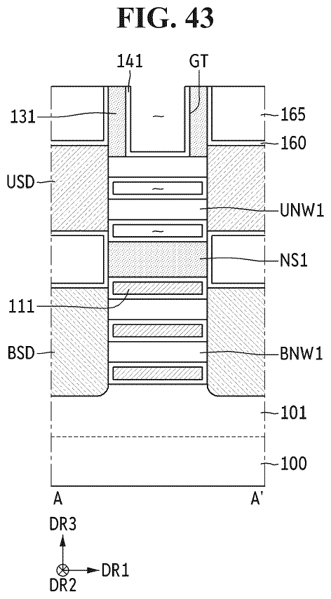

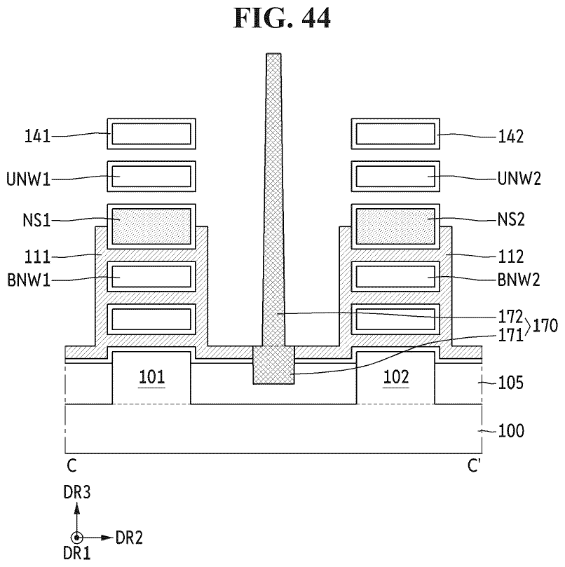

Referring to FIGS. 43 and 44, the second protective layer 80 (see FIGS. 40 and 42), the liner layer 90 (see FIG. 42), and the second sacrificial layer 60 (see FIGS. 40 and 42) may be etched. As a result, the second portion 172 of the gate cut 170 may be exposed inside the gate trench GT.

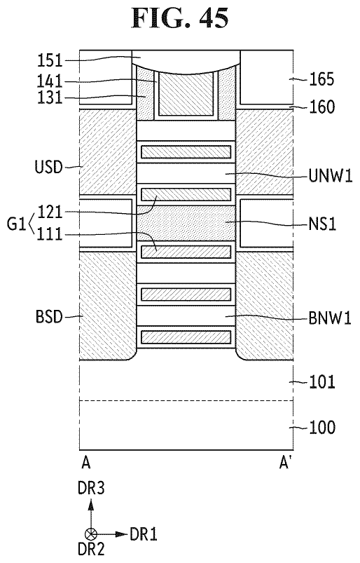

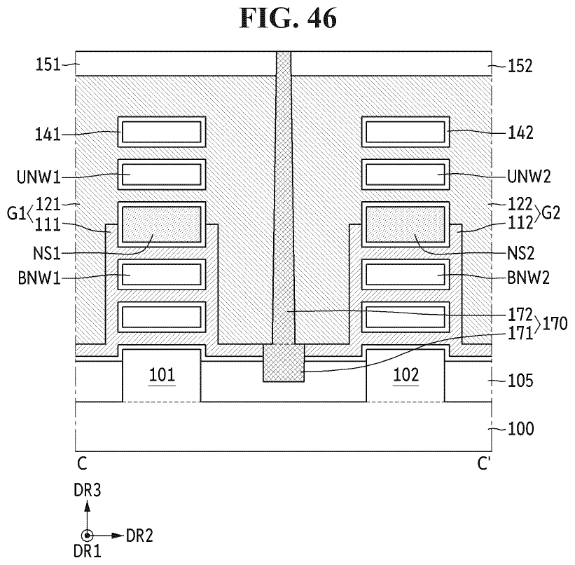

Referring to FIGS. 45 and 46, inside the gate trench GT (see FIG. 43), a first filling conductive layer 121 may be formed on the first conductive layer 111. Further, inside the gate trench GT (see FIG. 43), a second filling conductive layer 122 may be formed on the second conductive layer 112. Subsequently, after a portion of each of the first filling conductive layer 121, the first gate spacer 131, the first gate insulating layer 141, and the first etching stop layer 160 is etched, a first capping pattern 151 may be formed. Further, after a portion of each of the second filling conductive layer 122, the second gate spacer 132 (see FIG. 1), the second gate insulating layer 142, and the first etching stop layer 160 is etched, a second capping pattern 152 may be formed. For example, the upper surface of each of the first and second capping patterns 151, 152 may be formed on the same plane as the upper surface of the second portion 172 of the gate cut 170.

Referring to FIGS. 2 to 4, the first and second source/drain contacts CA1, CA2, the silicide layer SL, the first and second gate contacts CB1, CB2, the second etching stop layer 180, the second interlayer insulating layer 185, and the first and second vias V1, V2 may be formed. Through such a fabrication process, the semiconductor device shown in FIGS. 2 to 4 may be fabricated.

For example, if the gate cut is formed before the dummy gate DG is etched, the space between the gate cut and the plurality of nanosheets becomes relatively small, which may cause issues with the gate insulating layer and the gate electrode not being formed effectively. If the gate cut is formed after the gate electrode is formed, the process difficulty of etching the gate electrode including the metal is relatively high, which may cause issues where a portion of the gate electrode is not etched.

In a method of fabricating a semiconductor device according to some example embodiments of the present disclosure, a gate cut 170 may be formed before the dummy gate DG is etched and the first and second gate electrodes G1, G2 are formed. As a result, a method of fabricating a semiconductor device according to some embodiments of the present disclosure may limit and/or prevent the gate insulating layers 141, 142 and the gate electrodes G1, G2 from being ineffectively formed due to the gate cut 170, thereby improving the reliability of the gate cut 170. Furthermore, the method of fabricating a semiconductor device according to some embodiments of the present disclosure may reduce process difficulty by etching the second protective layer 80 to form the first trench T1 before the gate electrodes G1, G2 including metal are formed, and forming the gate cut 170 inside the first trench T1.

A semiconductor device according to some embodiments of the present disclosure fabricated by a fabrication method as described above includes a gate cut 170 including a first portion 171 and a second portion 172 disposed on an upper surface of the first portion 171. The width of the upper surface of the first portion 171 of the gate cut 170 in the second horizontal direction DR2 is formed larger than a width W3 of the bottom surface of the second portion 172 of the gate cut 170 in the second horizontal direction DR2. Further, the width W3 of the bottom surface of the second portion 172 of the gate cut 170 in the second horizontal direction DR2 is formed larger than the width W4 of the upper surface of the second portion 172 of the gate cut 170 in the second horizontal direction DR2.

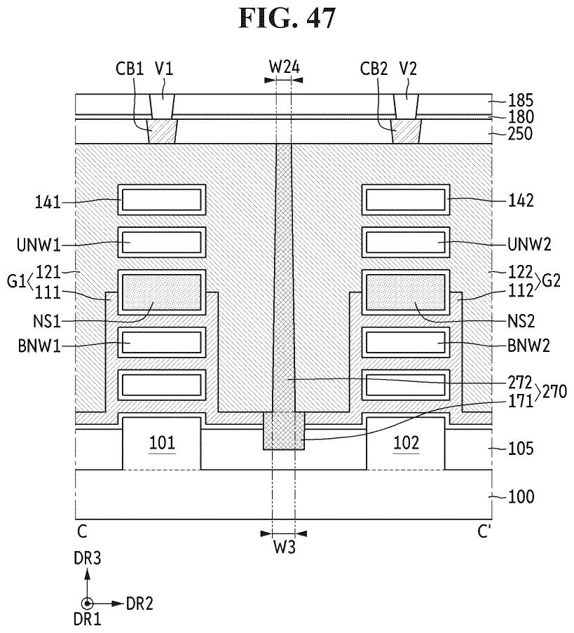

Hereinafter, a semiconductor device according to some example embodiments of the present disclosure will be described with reference to FIG. 47. The description will focus on differences from the semiconductor device shown in FIGS. 1 to 4.

FIG. 47 is a cross-sectional view for explaining a semiconductor device according to some example embodiments of the present disclosure.

Referring to FIG. 47, a semiconductor device according to some example embodiments of the present disclosure may have an upper surface of the second portion 272 of the gate cut 270 being in contact with a bottom surface of the capping pattern 250.

For example, the capping pattern 250 may extend in the second horizontal direction DR2 on the upper surface of each of the first gate electrode G1, the second gate electrode G2, and the second portion 272 of the gate cut 270. The capping pattern 250 disposed on the upper surface of the second gate electrode G2 may be integrally formed with the capping pattern 250 disposed on the upper surface of the first gate electrode G1. For example, the upper surface of the second portion 272 of the gate cut 270 may be formed on the same plane as the upper surface of each of the first and second gate electrodes G1, G2. For example, the width W3 of the bottom surface of the second portion 272 of the gate cut 270 in the second horizontal direction DR2 is larger than the width W24 of the upper surface of the second portion 272 of the gate cut 270 in the second horizontal direction DR2.

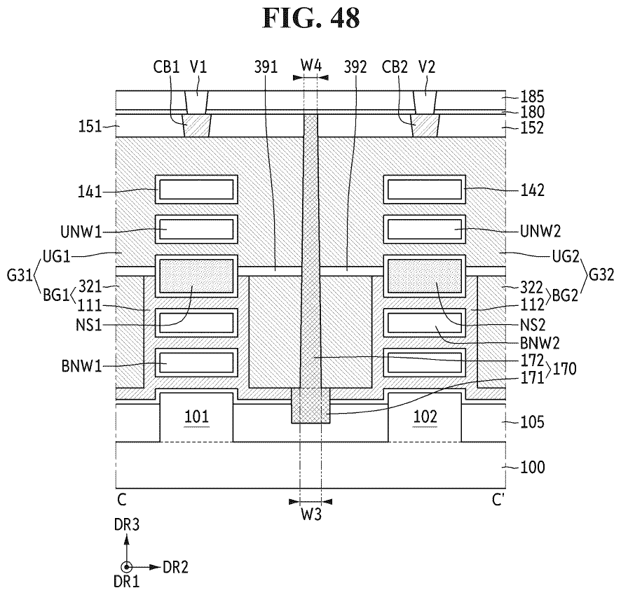

Hereinafter, a semiconductor device according to some example embodiments of the present disclosure will be described with reference to FIG. 48. The description will focus on differences from the semiconductor device shown in FIGS. 1 to 4.

FIG. 48 is a cross-sectional view for explaining a semiconductor device according to another several example embodiments of the present disclosure.

Referring to FIG. 48, a semiconductor device according to some example embodiments of the present disclosure may include a first gate electrode G31 including a first bottom gate electrode BG1 and a first upper gate electrode UG1, and a second gate electrode G32 including a second bottom gate electrode BG2 and a second upper gate electrode UG2.

For example, the first bottom gate electrode BG1 may surround a first plurality of bottom nanosheets BNW1 and a portion of the first nanosheet isolation layer NS1. The first bottom gate electrode BG1 may include a first conductive layer 111 and a first filling conductive layer 321. The first upper gate electrode UG1 may be spaced apart from the upper surface of the first bottom gate electrode BG1 in the vertical direction DR3. The first upper gate electrode UG1 may surround another portion of the first nanosheet isolation layer NS1 and the first plurality of upper nanosheets UNW1. The first upper gate electrode UG1 may include the first filling conductive layer 321.

For example, the second bottom gate electrode BG2 may surround a second plurality of bottom nanosheets BNW2 and a portion of the second nanosheet isolation layer NS2. The second bottom gate electrode BG2 may include a second conductive layer 112 and a second filling conductive layer 322. The second upper gate electrode UG2 may be spaced apart from the upper surface of the second bottom gate electrode BG2 in the vertical direction DR3. The second upper gate electrode UG2 may surround another portion of the second nanosheet isolation layer NS2 and the second plurality of upper nanosheets UNW2. The second upper gate electrode UG2 may include the second filling conductive layer 322.

The first gate isolation layer 391 may be disposed between the first bottom gate electrode BG1 and the first upper gate electrode UG1. For example, the first gate isolation layer 391 may be disposed on both sidewalls of the first nanosheet isolation layer NS1 in the second horizontal direction DR2. The second gate isolation layer 392 may be disposed between the second bottom gate electrode BG2 and the second upper gate electrode UG2. For example, the second gate isolation layer 392 may be disposed on both sidewalls of the second nanosheet isolation layer NS2 in the second horizontal direction DR2. For example, each of the first and second gate isolation layers 391, 392 may include an insulating material. However, the present disclosure is not limited thereto. In some other example embodiments, each of the first and second gate isolation layers 391, 392 may include a conductive material.

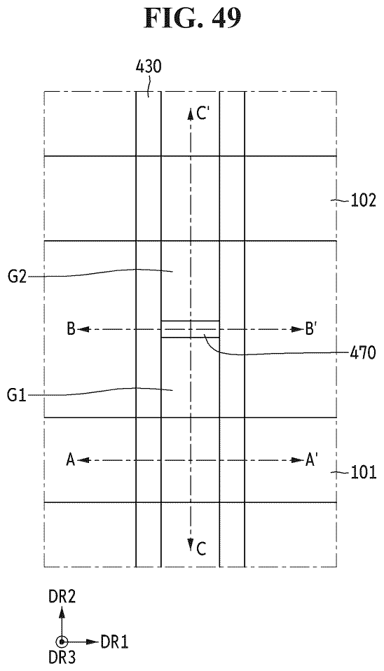

Hereinafter, a semiconductor device according to some example embodiments of the present disclosure will be described with reference to FIGS. 49 to 52. The description will focus on differences from the semiconductor devices shown in FIGS. 1 to 4.

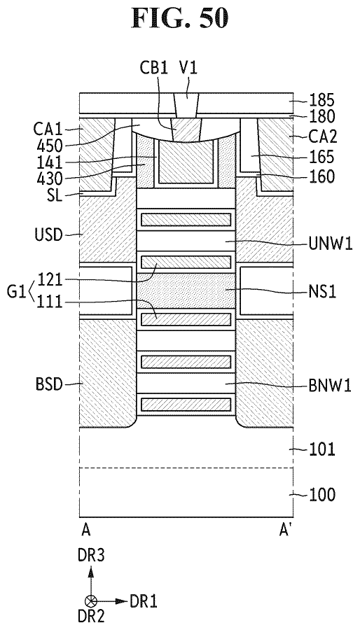

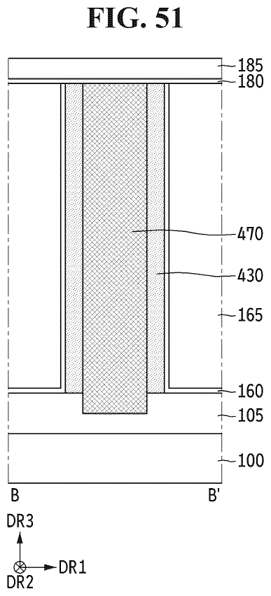

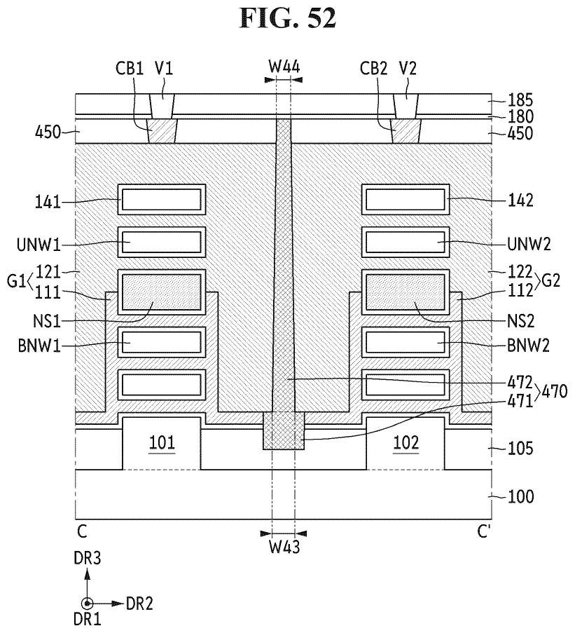

FIG. 49 is a layout diagram for explaining a semiconductor device according to some example embodiments of the present disclosure. FIG. 50 is a cross-sectional view taken along line A-A′ of FIG. 49. FIG. 51 is a cross-sectional view taken along line B-B′ of FIG. 49. FIG. 52 is a cross-sectional view taken along line C-C′ of FIG. 49.

Referring to FIGS. 49 to 52, a semiconductor device according to some example embodiments of the present disclosure may have gate cuts 470 disposed between gate spacer 430.

For example, the gate spacer 430 may be disposed on both sidewalls of each of the first and second gate electrodes G1, G2 in the first horizontal direction DR1. The gate spacer 430 disposed on both sidewalls of the first gate electrode G1 in the first horizontal direction DR1 may be integrally formed with the gate spacer 430 disposed on both sidewalls of the second gate electrode G2 in the first horizontal direction DR1. For example, both sidewalls of the gate cut 470 in the first horizontal direction DR1 may be in contact with the gate spacer 430. For example, both sidewalls of each of the first portion 471 of the gate cut 470 and the second portion 472 of the gate cut 470 in the first horizontal direction DR1 may be in contact with the gate spacer 430.

For example, the width of the upper surface of the first portion 471 of the gate cut 470 in the second horizontal direction DR2 is greater than the width W43 of the bottom surface of the second portion 472 of the gate cut 470 in the second horizontal direction DR2. For example, the width W43 of the bottom surface of the second portion 472 of the gate cut 470 in the second horizontal direction DR2 is greater than the width W44 of the upper surface of the second portion 472 of the gate cut 470 in the second horizontal direction DR2. For example, the capping pattern 450 disposed on the upper surface of the second gate electrode G2 may be spaced apart from the capping pattern 450 disposed on the upper surface of the first gate electrode G1 in the second horizontal direction DR2. However, the capping pattern 450 on the upper surface of the gate spacer 430 may be integrally formed. Although not shown, on the upper surface of the gate spacer 430, the capping pattern 450 may be in contact with both sidewalls of the second portion 472 of the gate cut 470 in the first horizontal direction DR1.

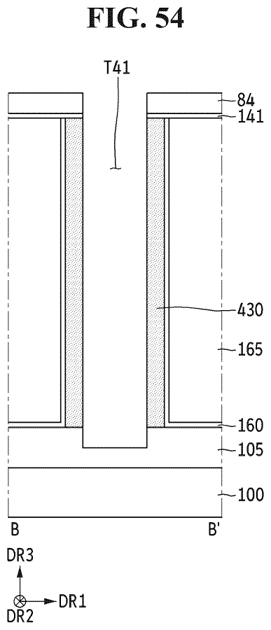

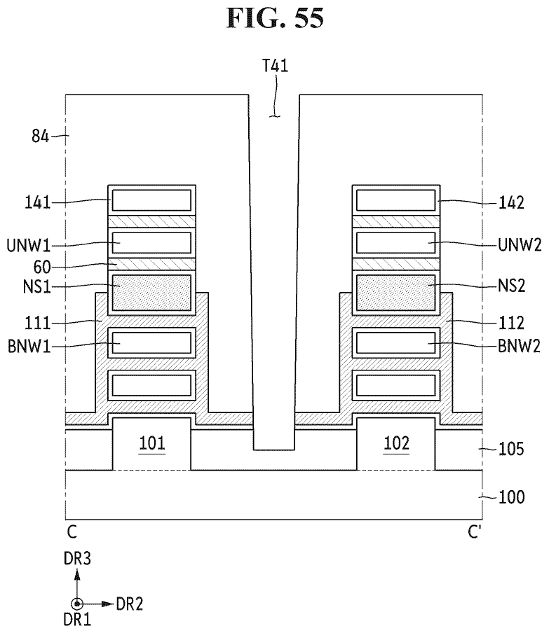

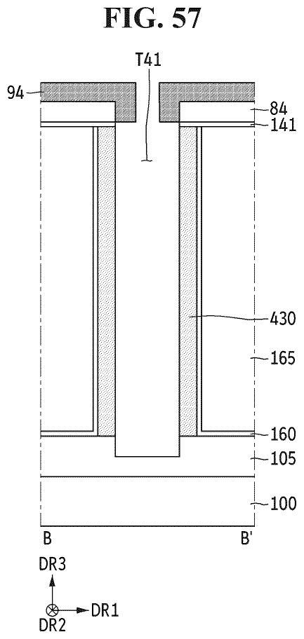

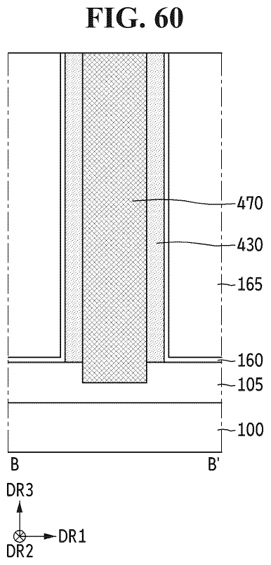

Hereinafter, a fabrication method for a semiconductor device according to some example embodiments of the present disclosure will be described with reference to FIGS. 49 to 61. The description will focus on differences from the fabrication method of the semiconductor device shown in FIGS. 5 to 46.

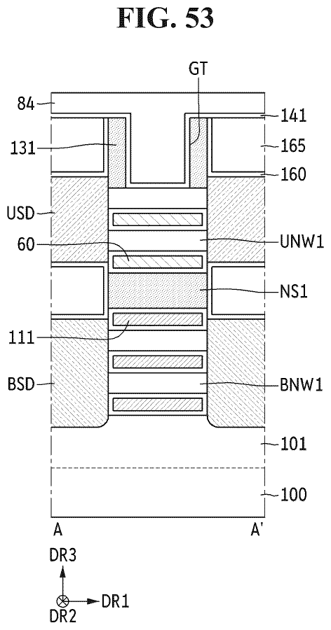

FIGS. 53 to 61 are intermediate stage diagrams for explaining a fabrication method of a semiconductor device according to another several example embodiments of the present disclosure.

Referring to FIGS. 53 to 55, after performing the fabrication process shown in FIGS. 5 to 34, a second protective layer 84 may be formed to fill the inside of the gate trench GT. For example, the second protective layer 84 may be formed on the gate insulating material layer 140 (see FIG. 33) formed on the upper surface of each of the gate spacer material layer 130 (see FIG. 33), the first etching stop layer 160, and the first interlayer insulating layer 165. For example, the second protective layer 84 may include a material in which a material including carbon (C) may be selectively deposited. For example, the second protective layer 84 may include BARC (Bottom Anti-Reflective Coating) or SOH (Spin On Hardmask). However, the present disclosure is not limited thereto.

Subsequently, a first trench T41 may be formed between the first active pattern 101 and the second active pattern 102. For example, the first trench T41 may be formed between the gate spacer 430. For example, the first trench T41 may penetrate each of the second protective layer 84, the gate spacer material layer 130 (see FIG. 33), the conductive material layer 110 (see FIGS. 33 and 34), and the gate insulating material layer 140 (see FIGS. 33 and 34) in the vertical direction DR3 to extend into the inside of the field insulating layer 105. For example, the width of the upper surface of the first trench T41 in the second horizontal direction DR2 may be formed greater than the width of the bottom surface of the first trench T41 in the second horizontal direction DR2.

For example, after the first trench T41 is formed, the gate spacer material layer 130 (see FIG. 33) may be defined as the gate spacer 430. For example, the first trench T41 may separate the conductive material layer 110 (see FIGS. 33 and 34) in the second horizontal direction DR2. After the first trench T41 is formed, the remaining conductive material layer 110 (see FIGS. 33 and 34) may be defined as the first conductive layer 111 and the second conductive layer 112. For example, the first trench T41 may separate the gate insulating material layer 140 (see FIGS. 33 and 34) in the second horizontal direction DR2. After the first trench T41 is formed, the remaining gate insulating material layer 140 (see FIGS. 33 and 34) may be defined as the first gate insulating layer 141 and the second gate insulating layer 142.

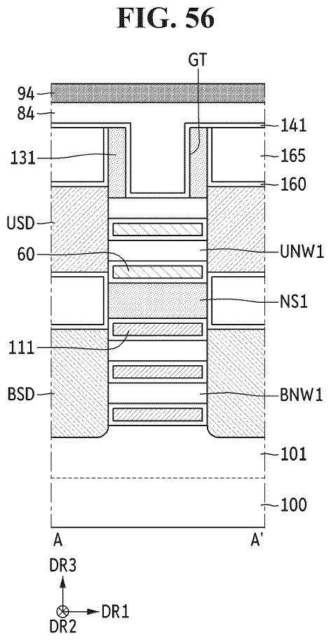

Referring to FIGS. 56 to 58, a liner layer 94 may be formed on the surface of the second protective layer 84 that is exposed on the sidewalls of the first trench T41. For example, the liner layer 94 may be formed only on the exposed surface of the second protective layer 84. The liner layer 94 is not formed on the surface of each of the field insulating layer 105, the first and second gate insulating layers 141, 142, the first and second conductive layers 111, 112, and the gate spacer 430 that are exposed through the first trench T41. For example, inside the first trench T41, each of the field insulating layer 105, the first and second gate insulating layers 141, 142, the first and second conductive layers 111, 112, and the gate spacer 430 may be exposed on the bottom surface of the liner layer 94.

For example, the thickness of the liner layer 94 formed on the sidewall of the first trench T41 in the second horizontal direction DR2 may increase continuously as it approaches the upper surface of the second protective layer 84. After the liner layer 94 is formed, the region formed on the bottom surface of the liner layer 94 may be defined as a second trench T42. After the liner layer 94 is formed, a region formed between the liner layer 94 inside the first trench T41 may be defined as a third trench T43. For example, the liner layer 94 may include the same material as the liner layer 90 shown in FIGS. 38 and 39.

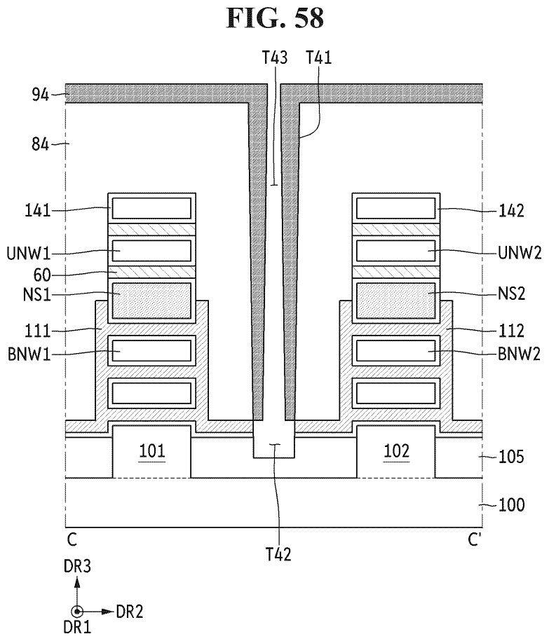

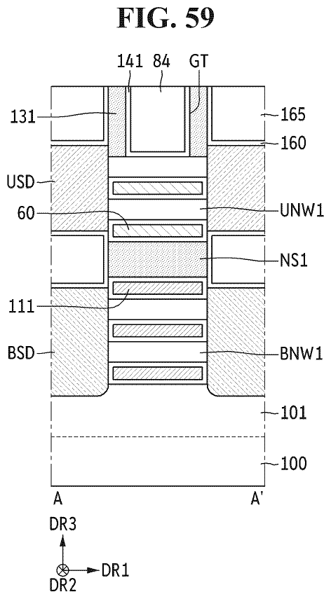

Referring to FIGS. 59 to 61, a gate cut 470 may be formed inside each of the second trench T42 (see FIG. 58) and the third trench T43 (see FIG. 58). For example, a portion of the gate cut 470 formed inside the second trench T42 (see FIG. 58) may be defined as a first portion 471 of the gate cut 470. For example, the remaining portion of the gate cut 470 formed inside the third trench T43 (see FIG. 58) may be defined as a second portion 472 of the gate cut 470. Subsequently, a planarization process may be performed to expose the upper surface of each of the first etching stop layer 160, the first interlayer insulating layer 165, and the first gate spacer 131.

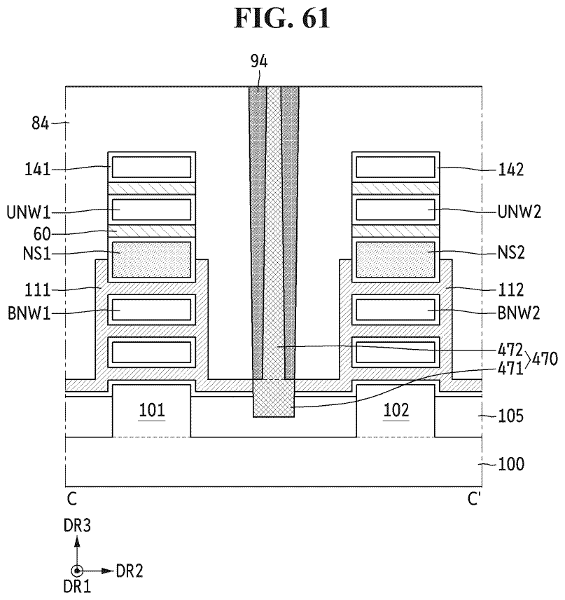

Referring to FIGS. 49 to 52, the second protective layer 84 (see FIGS. 59 and 61), the liner layer 94 (see FIG. 61), and the second sacrificial layer 60 (see FIGS. 59 and 61) may be etched. Subsequently, inside the gate trench GT (see FIG. 59), a first filling conductive layer 121 may be formed on the first conductive layer 111 and a second filling conductive layer 122 may be formed on the second conductive layer 112. Subsequently, after a portion of each of the first and second filling conductive layers 121, 122, the gate spacer 430, the first and second gate insulating layers 141, 142, and the first etching stop layer 160 is etched, the capping pattern 450 may be formed. Subsequently, the first and second source/drain contacts CA1, CA2, the silicide layer SL, the first and second gate contacts CB1, CB2, the second etching stop layer 180, the second interlayer insulating layer 185, and the first and second vias V1, V2 may be formed. Through such a fabrication process, the semiconductor device shown in FIGS. 49 to 52 may be fabricated.

While some example embodiments according to the present disclosure have been described above with reference to the accompanying drawings, it will be understood that the present disclosure is not limited to the above some example embodiments and may be fabricated in a variety of different forms, and those of ordinary skill in the art to which the present disclosure belongs, may recognize that it may be implemented in other specific forms without changing the technical idea or essential features of the present disclosure. Therefore, it should be understood that the above-described embodiments are examples in all respects and not restrictive.

What is claimed is:

1. A semiconductor device comprising:
a substrate;
a first active pattern on an upper surface of the substrate, the first active pattern extending in a first horizontal direction;
a second active pattern on the upper surface of the substrate, the second active pattern extending in the first horizontal direction, and the second active pattern being spaced apart from the first active pattern in a second horizontal direction different from the first horizontal direction;
a field insulating layer on the upper surface of the substrate, the field insulating layer surrounding sidewalls of the first active pattern and the second active pattern;
a first gate electrode on the first active pattern, the first gate electrode extending in the second horizontal direction;
a second gate electrode on the second active pattern, the second gate electrode extending in the second horizontal direction, and the second gate electrode being spaced apart from the first gate electrode in the second horizontal direction; and
a gate cut separating the first gate electrode and the second gate electrode in the second horizontal direction, the gate cut comprising a first portion at least partially inside the field insulating layer and a second portion on an upper surface of the first portion, the second portion extending in a vertical direction,
wherein sidewalls of the second portion of the gate cut that are opposite each other in the second horizontal direction have continuous sloped profile, and
wherein a width along the second horizontal direction of a bottom surface of the second portion of the gate cut is greater than a width along the second horizontal direction of an upper surface of the second portion of the gate cut.

2. The semiconductor device of claim 1, wherein a width along the second horizontal direction of the upper surface of the first portion of the gate cut is greater than the width along the second horizontal direction of the bottom surface of the second portion of the gate cut.

3. The semiconductor device of claim 1, wherein at least a portion of the upper surface of the first portion of the gate cut contacts the first gate electrode and the second gate electrode.

4. The semiconductor device of claim 1, further comprising:
a first plurality of bottom nanosheets stacked on the first active pattern, the first plurality of bottom nanosheets being spaced apart from each other in the vertical direction, and the first plurality of bottom nanosheets being surrounded by the first gate electrode; and
a second plurality of bottom nanosheets stacked on the second active pattern, the second plurality of bottom nanosheets being spaced apart from each other in the vertical direction, the second plurality of bottom nanosheets being spaced apart from the first plurality of bottom nanosheets in the second horizontal direction, and the second plurality of bottom nanosheets being surrounded by the second gate electrode,
wherein the second portion of the gate cut is between the first plurality of bottom nanosheets and the second plurality of bottom nanosheets.

5. The semiconductor device of claim 4, further comprising:
a first nanosheet isolation layer on an upper surface of an uppermost nanosheet of the first plurality of bottom nanosheets, the first nanosheet isolation layer comprising a first insulating material;
a second nanosheet isolation layer on an upper surface of an uppermost nanosheet of the second plurality of bottom nanosheets, the second nanosheet isolation layer comprising a second insulating material;
a first plurality of upper nanosheets stacked on an upper surface of the first nanosheet isolation layer, the first plurality of upper nanosheets being spaced apart from each other in the vertical direction; and
a second plurality of upper nanosheets stacked on an upper surface of the second nanosheet isolation layer, the second plurality of upper nanosheets being spaced apart from each other in the vertical direction,
wherein the second portion of the gate cut is between the first plurality of upper nanosheets and the second plurality of upper nanosheets.

6. The semiconductor device of claim 1, wherein the sidewalls of the second portion of the gate cut respectively contact the first gate electrode and the second gate electrode.

7. The semiconductor device of claim 1, further comprising:
a capping pattern on an upper surface of the first gate electrode and an upper surface of the second gate electrode, the capping pattern extending in the second horizontal direction,
wherein the sidewalls of the second portion of the gate cut contact the capping pattern.

8. The semiconductor device of claim 7, wherein the capping pattern comprises:
a first capping pattern on the upper surface of the first gate electrode, the first capping pattern extending in the second horizontal direction; and
a second capping pattern on the upper surface of the second gate electrode, the second capping pattern extending in the second horizontal direction, and
wherein the second portion of the gate cut separates the first capping pattern and the second capping pattern in the second horizontal direction.

9. The semiconductor device of claim 1, further comprising:
a capping pattern on an upper surface of the first gate electrode and an upper surface of the second gate electrode, the capping pattern extending in the second horizontal direction,
wherein the upper surface of the second portion of the gate cut contacts a bottom surface of the capping pattern.

10. The semiconductor device of claim 1, further comprising:
a first gate spacer on sidewalls of the first gate electrode that are opposite each other in the first horizontal direction; and
a second gate spacer on sidewalls of the second gate electrode that are opposite each other in the first horizontal direction, the second gate spacer being spaced apart from the first gate spacer in the second horizontal direction,
wherein a width of the gate cut along the second horizontal direction between the first gate spacer and the second gate spacer is greater than a width of the gate cut along the second horizontal direction between the first gate electrode and the second gate electrode.

11. The semiconductor device of claim 1, further comprising:
a first gate spacer on sidewalls of the first gate electrode that are opposite each other in the first horizontal direction; and
a second gate spacer on sidewalls of the second gate electrode that are opposite each other in the first horizontal direction,
wherein the gate cut is between the first gate spacer and the second gate spacer.

12. The semiconductor device of claim 11, wherein the sidewalls of the second portion of the gate cut contact the first gate spacer and the second gate spacer.

13. A semiconductor device comprising:
a substrate;
a first active pattern on an upper surface of the substrate, the first active pattern extending in a first horizontal direction;
a second active pattern on the upper surface of the substrate, the second active pattern extending in the first horizontal direction, the second active pattern being spaced apart from the first active pattern in a second horizontal direction different from the first horizontal direction;
a first plurality of bottom nanosheets stacked on the first active pattern, the first plurality of bottom nanosheets being spaced apart from each other in a vertical direction;
a second plurality of bottom nanosheets stacked on the second active pattern, the second plurality of bottom nanosheets being spaced apart from each other in the vertical direction, and the second plurality of bottom nanosheets being spaced apart from the first plurality of bottom nanosheets in the second horizontal direction;
a first gate electrode on the first active pattern, the first gate electrode extending in the second horizontal direction, and the first gate electrode surrounding the first plurality of bottom nanosheets;
a second gate electrode on the second active pattern, the second gate electrode extending in the second horizontal direction, the second gate electrode being spaced apart from the first gate electrode in the second horizontal direction, and the second gate electrode surrounding the second plurality of bottom nanosheets; and
a gate cut between the first plurality of bottom nanosheets and the second plurality of bottom nanosheets, the gate cut separating the first gate electrode and the second gate electrode in the second horizontal direction, and the gate cut contacting the first gate electrode and the second gate electrode,
the gate cut comprising a first portion, and a second portion on an upper surface of the first portion, the first portion and the second portion extending in the vertical direction,
wherein sidewalls of the second portion of the gate cut that are opposite each other in the second horizontal direction have continuous sloped profile, and
wherein a width along the second horizontal direction of a bottom surface of the second portion of the gate cut is greater than a width along the second horizontal direction of an upper surface of the second portion of the gate cut.

14. The semiconductor device of claim 13, wherein a width along the second horizontal direction of the upper surface of the first portion of the gate cut is greater than the width along the second horizontal direction of the bottom surface of the second portion of the gate cut.

15. The semiconductor device of claim 13, wherein a distance along the second horizontal direction between the first plurality of bottom nanosheets and the second portion of the gate cut is greater than a distance along the second horizontal direction between the first active pattern and the first portion of the gate cut.

16. The semiconductor device of claim 13, wherein the first gate electrode comprises:
a conductive layer surrounding the first plurality of bottom nanosheets, the conductive layer being in contact with a sidewall of the first portion of the gate cut that faces in the second horizontal direction; and
a filling conductive layer on the conductive layer, the filling conductive layer being in contact with at least a portion of the upper surface of the first portion of the gate cut, and the filling conductive layer being in contact with a sidewall from among the sidewalls of the second portion of the gate cut.

17. The semiconductor device of claim 13, further comprising:
a first nanosheet isolation layer on an upper surface of an uppermost nanosheet of the first plurality of bottom nanosheets, the first nanosheet isolation layer comprising a first insulating material;
a second nanosheet isolation layer on an upper surface of an uppermost nanosheet of the second plurality of bottom nanosheets, the second nanosheet isolation layer comprising a second insulating material;
a first plurality of upper nanosheets stacked on an upper surface of the first nanosheet isolation layer, the first plurality of upper nanosheets being spaced apart from each other in the vertical direction; and
a second plurality of upper nanosheets stacked on an upper surface of the second nanosheet isolation layer, the second plurality of upper nanosheets being spaced apart from each other in the vertical direction,
wherein the first gate electrode surrounds each of the first nanosheet isolation layer and the first plurality of upper nanosheets, and the second gate electrode surrounds each of the second nanosheet isolation layer and the second plurality of upper nanosheets.

18. The semiconductor device of claim 17, wherein the first gate electrode comprises:
a bottom gate electrode surrounding the first plurality of bottom nanosheets; and
an upper gate electrode surrounding the first plurality of upper nanosheets, the upper gate electrode being spaced apart from the bottom gate electrode in the vertical direction.

19. The semiconductor device of claim 13, further comprising:
a first gate spacer on sidewalls of the first gate electrode that are opposite each other in the first horizontal direction; and
a second gate spacer on sidewalls of the second gate electrode that are opposite each other in the first horizontal direction, the second gate spacer being spaced apart from the first gate spacer in the second horizontal direction,
wherein a width of the gate cut along the second horizontal direction between the first gate spacer and the second gate spacer is greater than a width of the gate cut along the second horizontal direction between the first gate electrode and the second gate electrode.

20. A semiconductor device comprising:
a substrate;
a first active pattern on an upper surface of the substrate, the first active pattern extending in a first horizontal direction;
a second active pattern on the upper surface of the substrate, the second active pattern extending in the first horizontal direction, and the second active pattern being spaced apart from the first active pattern in a second horizontal direction different from the first horizontal direction;
a field insulating layer on the upper surface of the substrate, the field insulating layer surrounding sidewalls of the first active pattern and the second active pattern;
a first plurality of bottom nanosheets stacked on the first active pattern, the first plurality of bottom nanosheets being spaced apart from each other in a vertical direction;
a second plurality of bottom nanosheets stacked on the second active pattern, the second plurality of bottom nanosheets being spaced apart from each other in the vertical direction, and the second plurality of bottom nanosheets being spaced apart from the first plurality of bottom nanosheets in the second horizontal direction;
a first nanosheet isolation layer on an upper surface of an uppermost nanosheet of the first plurality of bottom nanosheets, the first nanosheet isolation layer comprising a first insulating material;
a second nanosheet isolation layer on an upper surface of an uppermost nanosheet of the second plurality of bottom nanosheets, the second nanosheet isolation layer comprising a second insulating material;
a first plurality of upper nanosheets stacked on an upper surface of the first nanosheet isolation layer, the first plurality of upper nanosheets being spaced apart from each other in the vertical direction;
a second plurality of upper nanosheets stacked on an upper surface of the second nanosheet isolation layer, the second plurality of upper nanosheets being spaced apart from each other in the vertical direction;
a first gate electrode on the first active pattern, the first gate electrode extending in the second horizontal direction, and the first gate electrode surrounding each of the first plurality of bottom nanosheets, the first nanosheet isolation layer, and the first plurality of upper nanosheets;
a second gate electrode on the second active pattern, the second gate electrode extending in the second horizontal direction, the second gate electrode being spaced apart from the first gate electrode in the second horizontal direction, and the second gate electrode surrounding each of the second plurality of bottom nanosheets, the second nanosheet isolation layer, and the second plurality of upper nanosheets;
a first gate spacer on sidewalls of the first gate electrode that are opposite each other in the first horizontal direction;
a second gate spacer on sidewalls of the second gate electrode that are opposite each other in the first horizontal direction, the second gate spacer being spaced apart from the first gate spacer in the second horizontal direction; and
a gate cut between the first plurality of bottom nanosheets and the second plurality of bottom nanosheets, the gate cut separating the first gate electrode and the second gate electrode from each other in the second horizontal direction, the gate cut separating the first gate spacer and the second gate spacer from each other in the second horizontal direction, and the gate cut being in contact with the first gate electrode and the second gate electrode, and
the gate cut comprising a first portion at least partially inside of the field insulating layer, and a second portion on an upper surface of the first portion, the second portion extending in the vertical direction,
wherein a sidewall of the second portion of the gate cut along the second horizontal direction has a continuous sloped profile,
wherein a width along the second horizontal direction of a bottom surface of the second portion of the gate cut is greater than a width along the second horizontal direction of an upper surface of the second portion of the gate cut, and
wherein a width along the second horizontal direction of the gate cut between the first gate spacer and the second gate spacer is greater than a width along the second horizontal direction of the gate cut between the first gate electrode and the second gate electrode.
